(19) United States
(12) Patent Application Publication
(10) Pub. No.: US 2026/0289914 A1
(43) Pub. Date: Sep. 24, 2026

(54) SYSTEM

(71) Applicant: SoftBank Group Corp., Tokyo (JP)

(72) Inventor: Rio JINGU, Tokyo (JP)

(73) Assignee: SoftBank Group Corp., Tokyo (JP)

(21) Appl. No.: 19/567,003

(22) Filed: Mar. 14, 2026

(30) Foreign Application Priority Data
Mar. 19, 2025 (JP) 2025-045102

(51) Int. Cl. G06T 19/00; A63F 13/67; G06F 30/27; G06F 40/284; G06N 3/0475; G06T 3/4092; G06T 9/00; G06T 13/20; G06T 13/40; G06T 17/20; G06V 10/764; G06V 40/16; G10L 13/027; G10L 25/63

(52) U.S. Cl. CPC G06T 19/00; G06F 30/27; G06F 40/284; G06N 3/0475; G06T 3/4092; G06T 9/001; G06T 13/205; G06T 13/40; G06T 17/20; G10L 13/027; A63F 13/67; G06T 2210/21; G06T 2210/61; G06V 10/764; G06V 40/174; G10L 25/63

(57) ABSTRACT

A system includes a processor configured to: provide an interface allowing a user to enter a virtual space and participate in activities toward a specific objective; provide communication means enabling real-time cooperation and information sharing among participants; provide an AI-equipped virtual character that dynamically responds to user actions to assist activity progress; use a generative AI model to receive a user prompt instructing generation of a specific scenario, generate a user experience scenario based on the prompt, and stream the generated scenario data to the user's device; and use an emotion engine that analyzes facial expressions, voice, or behavior to recognize user emotion and adjust the virtual space experience accordingly.

### CROSS-REFERENCE TO RELATED APPLICATION

This application is based on and claims priority under 35 USC 119 from Japanese Patent Application No. 2025-045102 filed on Mar. 19, 2025, the disclosure of which is incorporated by reference herein.

### BACKGROUND

### Technical Field

The present disclosure relates to a system.

### Related Art

Japanese Patent Application Laid-Open (JP-A) No. 2022-180282 discloses a persona chatbot control method executed by at least one processor. The method includes steps of: receiving a user utterance, adding the user utterance to a prompt including a description of a chatbot character and an associated instruction sentence, encoding the prompt, and inputting the encoded prompt to a language model to generate a chatbot utterance responding to the user utterance.

Conventional virtual space and metaverse systems mainly provide predetermined game scenarios and static communication functions, and therefore fail to sufficiently adapt to individual users' intentions, emotions, and cooperative play styles. In typical systems, user experiences are constrained by fixed storylines and scripted non-player characters, which limits the ability to generate personalized scenarios in real time based on user prompts or changing emotional states. Furthermore, existing systems generally do not integrate, in a unified architecture, immersive virtual reality or augmented reality interfaces, real-time multi-user collaboration, generative AI-driven scenario creation, and emotion-aware adaptive control of the virtual environment. As a result, there is a need for a system that can dynamically generate and stream individualized experience scenarios according to natural-language prompts from users, support cooperative activities via real-time communication with other participants, and recognize user emotions in order to adjust virtual space experiences through interaction with AI-equipped virtual characters.

### SUMMARY

In order to solve the above problems, the present invention provides a system comprising a processor, wherein the processor is configured to provide an interface that allows a user to enter a virtual space and participate in activities for achieving a specific objective, and to provide a communication means that allows the user to cooperate with other participants for achieving the objective and to share information in real time. The processor is further configured to provide a virtual character equipped with artificial intelligence that is visited by the user and that dynamically responds according to user actions to provide information that assists progress of the activities, and to use a generative AI model to receive, from the user, a prompt that instructs generation of a specific scenario, generate a user experience scenario based on the prompt, and stream generated scenario data to a device of the user. Moreover, the processor is configured to use an emotion engine that analyzes facial expressions, voice, or behavior of the user in order to recognize an emotion of the user and adjust an experience within the virtual space. In certain embodiments, the processor provides the interface by using virtual reality or augmented reality technology so as to deliver an immersive environment, and causes the artificial-intelligence-equipped virtual character to dynamically respond according to both user actions and user emotions, thereby supplying information and events that enhance the user's experience within the virtual space.

The term “virtual space” refers to a computer-generated environment in which one or more users can perceive, navigate, and interact with digital objects, characters, and other users through an electronic device.

The term “activity” refers to any task, quest, interaction, game play, or operation that a user performs or participates in within the virtual space for the purpose of achieving a specific objective.

The term “specific objective” refers to a defined goal or target to be achieved by the user within the virtual space, such as completing a quest, solving a problem, exploring a location, or reaching a game-ending condition.

The term “interface” refers to hardware, software, or a combination thereof that enables the user to access, view, and interact with the virtual space, including but not limited to graphical user interfaces, input/output components, and VR/AR presentation modules.

The term “communication means” refers to one or more functions, modules, or services that enable the user to exchange information with other participants in the virtual space in real time, including text chat, voice communication, video communication, signaling, or other data exchange mechanisms.

The term “participant” refers to any human user or computer-controlled agent that takes part in activities within the virtual space and can cooperate or interact with other users.

The term “virtual character” refers to a computer-generated entity, such as an avatar, non-player character (NPC), or computer player (CP), that appears in the virtual space and is capable of interacting with the user.

The term “virtual character equipped with artificial intelligence” refers to a virtual character whose behavior, responses, or actions are determined at least in part by one or more artificial intelligence techniques, such as rule-based systems, machine learning models, or generative models, enabling dynamic or context-dependent interaction with the user.

The term “generative AI model” refers to an artificial intelligence model that generates content, such as text, images, audio, or structured scenario data, in response to input data including user prompts or context information.

The term “prompt” refers to an input provided by the user, including text, voice, or other data, that instructs the generative AI model to generate a specific scenario or content for the user's experience.

The term “user experience scenario” refers to a structured set of events, narrative elements, interactions, and environmental configurations generated for the user by the generative AI model based on the prompt, and used to control or define the user's experience within the virtual space.

The term “scenario data” refers to digital data that represents the user experience scenario, including but not limited to event scripts, dialog content, object placements, environmental parameters, and state transitions.

The term “streaming” refers to transmitting scenario data or other content from the system to the user's device in a time-sequenced manner that allows the user to begin experiencing the content before transmission of the entire data set is completed.

The term “emotion engine” refers to a software module, hardware module, or combination thereof that analyzes user-related input data, such as facial expressions, voice characteristics, or behavioral patterns, to estimate or recognize the user's emotional state and to control or adjust the virtual space based on the recognized emotion.

The term “emotion” refers to an internal affective state of the user, such as happiness, sadness, fear, excitement, frustration, or calmness, which is inferred by the emotion engine from observable indicators.

The term “facial expressions” refers to visual features or movements of the user's face, such as changes in eyes, eyebrows, mouth, or overall facial configuration, captured by a camera or sensor and used as input to the emotion engine.

The term “voice” refers to audio signals generated by the user, including speech content and paralinguistic features such as pitch, tone, volume, and rhythm, which are analyzed by the emotion engine to infer user emotion.

The term “behavior” refers to observable actions or interaction patterns of the user in the virtual space, including movement patterns, input timing, selection of options, and interaction frequency, which can be used by the emotion engine to estimate the user's emotional state. The term “immersive experience” refers to a quality of interaction in which the user perceives a high level of presence or involvement in the virtual space, typically achieved by presenting sensory information that aligns with the user's movements and perspective.

The term “virtual reality (VR) technology” refers to technologies that provide a fully computer-generated environment to the user, usually through a head-mounted display and motion-tracking devices, thereby occluding or replacing the real-world view.

The term “augmented reality (AR) technology” refers to technologies that superimpose or integrate computer-generated objects or information onto the user's view of the real world, typically through transparent displays, cameras, or optical see-through devices.

The term “user device” refers to any electronic device used by the user to access the system, including but not limited to head-mounted displays, AR glasses, personal computers, game consoles, smartphones, tablets, or dedicated terminals.

### BRIEF DESCRIPTION OF THE DRAWINGS

Exemplary embodiments of the present disclosure will be described in detail based on the following figures, wherein:

FIG. 1 is a schematic diagram illustrating an example of a configuration of a data processing system according to a first exemplary embodiment;

FIG. 2 is a schematic diagram illustrating an example of relevant functions of a data processing device and a smart device according to the first exemplary embodiment;

FIG. 3 is a schematic diagram illustrating an example of a configuration of a data processing system according to a second exemplary embodiment;

FIG. 4 is a schematic diagram illustrating an example of relevant functions of a data processing device and smart glasses according to the second exemplary embodiment;

FIG. 5 is a schematic diagram illustrating an example of a configuration of a data processing system according to a third exemplary embodiment;

FIG. 6 is a schematic diagram illustrating an example of relevant functions of a data processing device and a headset-type terminal according to the third exemplary embodiment;

FIG. 7 is a schematic diagram illustrating an example of a configuration of a data processing system according to a fourth exemplary embodiment;

FIG. 8 is a schematic diagram illustrating an example of relevant functions of a data processing device and a robot according to the fourth exemplary embodiment;

FIG. 9 illustrates an emotion map mapping plural emotions;

FIG. 10 illustrates an emotion map mapping plural emotions;

FIG. 11 is a sequence diagram showing the flow of data processing system processing in Example 1;

FIG. 12 is a sequence diagram showing the flow of data processing system processing in Application Example 1;

FIG. 13 is a sequence diagram showing the flow of data processing system processing in Example 2; and

FIG. 14 is a sequence diagram showing the flow of data processing system processing in Application Example 2.

### DETAILED DESCRIPTION

Description follows regarding an example of exemplary embodiments of a system according to technology disclosed herein, with reference to the appended drawings.

First, explanation follows regarding terminology employed in the following description.

In the following exemplary embodiments, a reference-numeral-appended processor (hereinafter simply referred to as “processor”) may be implemented by a single computation unit, and may be implemented by a combination of plural computation units. The processor may be implemented by a single type of computation unit, or may be implemented by a combination of plural types of computation units. Examples of computation unit include a central processing unit (CPU), a graphics processing unit (GPU), a general-purpose computing on graphics processing units (GPGPU), an accelerated processing unit (APU), and the like.

In the following exemplary embodiments, random access memory (RAM) appended with a reference numeral is memory temporarily stored with information, and is employed as working memory by a processor.

In the following exemplary embodiments, reference-numeral-appended storage is a single or plural non-volatile storage devices for storing various programs and various parameters and the like. Examples of non-volatile storage devices include flash memory (such as a solid state drive (SSD)), a magnetic disk (for example, a hard disk), magnetic tape, and the like.

In the following exemplary embodiments, a reference-numeral-appended communication interface (I/F) is an interface including a communication processor and an antenna or the like. The communication I/F has the role of communicating between plural computers. An example of a communication standard applied for the communication I/F is a wireless communication standard, such as a Fifth Generation Mobile Communication System (5G), Wi-Fi (registered trademark), Bluetooth (registered trademark), and the like.

In the following exemplary embodiments “A and/or B” has the same definition as “at least one out of A or B”. Namely, “A and/or B” may mean A alone, may mean B alone, or may mean a combination of A and B. Moreover, similar logic to “A and/or B” is applied when “and/or” is employed to link three or more items in the present specification.

### First Exemplary Embodiment

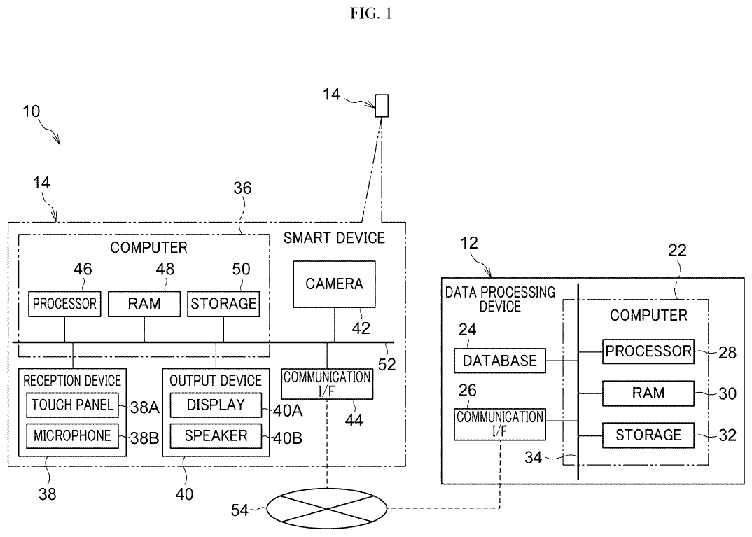

FIG. 1 illustrates an example of a configuration of a data processing system 10 according to a first exemplary embodiment.

As illustrated in FIG. 1, the data processing system 10 includes a data processing device 12 and a smart device 14. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart device 14 includes a computer 36, a reception device 38, an output device 40, a camera 42, and a communication I/F 44. The computer 36 includes a processor 46, RAM 48, and storage 50. The processor 46, the RAM 48, and the storage 50 are connected to a bus 52. The reception device 38, the output device 40, the camera 42, and the communication I/F 44 are also connected to the bus 52.

The reception device 38 includes a touch panel 38A, a microphone 38B, and the like for receiving user input. The touch panel 38A receives user input from contact of a pointer (for example, a pen, a finger, or the like) by detecting contact of the pointer. The microphone 38B receives spoken user input by detecting speech of the user. A control unit 46A in the processor 46 transmits data representing the user input received by the touch panel 38A and the microphone 38B to the data processing device 12. A specific processing unit 290 in the data processing device 12 acquires the data indicating the user input.

The output device 40 includes a display 40A, a speaker 40B, and the like for presenting data to a user 20 by outputting the data in an expression format perceivable by the user 20 (for example, audio and/or text). The display 40A displays visual information such as text, images, or the like under instruction from the processor 46. The speaker 40B outputs audio under instruction from the processor 46. The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like.

The communication I/F 44 is connected to the network 54. The communication I/F 44 and the communication I/F 26 perform the role of exchanging various information between the processor 46 and the processor 28 over the network 54.

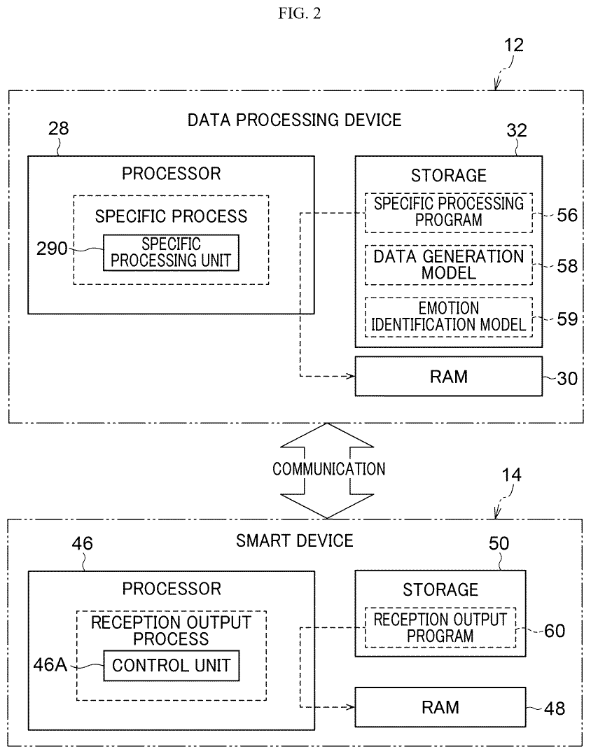

FIG. 2 illustrates an example of relevant functions of the data processing device 12 and the smart device 14.

As illustrated in FIG. 2, specific processing is performed by the processor 28 in the data processing device 12. A specific processing program 56 is stored in the storage 32. The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

A data generation model 58 and an emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart device 14. A reception and output program 60 is stored in the storage 50. The reception and output program 60 is employed by the data processing system 10 in combination with the specific processing program 56. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48. Note that a configuration may be adopted in which a similar data generation model and emotion identification model to the data generation model 58 and the emotion identification model 59 are included in the smart device 14, and these models are used to perform similar processing to the specific processing unit 290. The reception and output program is implemented by the processor 46 operating as the control unit 46A according to the reception and output program 60 executed in the RAM 48.

Note that devices other than the data processing device 12 may include the data generation model 58. For example, a server device (for example, a generation server) may include the data generation model 58. In such cases, the data processing device 12 performs communication with the server device including the data generation model 58 to obtain a processing result (prediction result or the like) obtained using the data generation model 58. The data processing device 12 may be a server device, and may be a terminal device owned by the user (for example, a mobile phone, a robot, a home electrical appliance, or the like). Next, description follows regarding an example of processing by the data processing system 10 according to the first exemplary embodiment.

### Example 1

Description follows regarding a flow of the specific processing in an Example 1. The units of the system described below are implemented by the data processing device 12 and the smart device 14. The data processing device 12 is called a “server” and the smart device 14 is called a “terminal”.

Conventional virtual reality and augmented reality systems typically rely on pre-authored, static scenarios that are executed in a fixed manner on client devices or servers. In such systems, scenario logic, non-player character behavior, and event flows are predefined and do not flexibly change in response to high-level user instructions, complex user context, or emotional state. As a result, these systems cannot adapt the virtual environment or interaction patterns at runtime in a granular, context-aware way, and therefore provide limited personalization and immersion.

Further, in many known systems, artificial intelligence components are used only for isolated tasks, such as simple dialogue generation or basic recommendation, without being tightly integrated with the core simulation loop of the virtual space. Scenario changes produced by artificial intelligence, if any, are often processed offline or with considerable delay, and are not synchronized with real-time streaming and interaction handling. This architecture leads to fragmented processing pipelines, increased latency, and inconsistent user experiences. Additionally, existing architectures often place much of the scenario processing burden on terminals, which have constrained computation and memory resources. Terminals are typically required to manage local scenario branching, non-player character logic, and rendering simultaneously, which can lead to reduced frame rates, increased latency, and degraded responsiveness, particularly when multiple users and complex environments are involved. These issues limit scalability and make it difficult to maintain high-quality, low-latency experiences over heterogeneous networks.

Existing systems also inadequately leverage emotional state information derived from multimodal user input. Although some systems may detect simple user reactions, they do not integrate emotion estimation into the central control of scenario generation, event scheduling, and virtual character behavior. Consequently, these systems fail to dynamically alter the scenario structure and presentation strategies in a way that is directly tied to real-time emotional feedback, and thus cannot optimize user engagement and comfort.

Moreover, conventional multi-user virtual environments often maintain separate logic for network synchronization, artificial intelligence behavior, and content streaming, increasing implementation complexity and causing redundant state management. In particular, there is no unified mechanism that uses generative artificial intelligence models, driven by prompt sentences enriched with detailed context, as an authoritative source for both initial scenario generation and subsequent dynamic updates of goals, events, and virtual character behaviors during live sessions.

Therefore, there is a need for an improved computer technology that centralizes scenario control, artificial intelligence reasoning, emotion-aware adaptation, and low-latency streaming on a server-side processor, while keeping terminals lightweight. Such a technology should allow the server to generate structured scenario data from user-provided prompt sentences, integrate this data into a real-time virtual space simulation, continuously update the simulation based on user actions and emotional state, and stream the resulting simulation to terminals. Addressing this need would improve processing efficiency, scalability, synchronization accuracy, and adaptability of virtual and augmented reality systems, thereby providing a more immersive and responsive experience.

The specific processing by the specific processing unit 290 of the data processing device 12 in Example 1 is realized by the following means.

The present invention provides a server comprising a processor configured to provide, via an information processing apparatus, a display interface and an input interface that allow a user to enter a virtual space and participate in activities for achieving a predetermined goal; provide a communication function that allows the user to cooperate with other participants for achieving the predetermined goal, and share, in real time, position information, operation information, and state information in the virtual space; place, in the virtual space, a virtual character having an artificial intelligence function, dynamically update response content and behavior patterns of the virtual character in accordance with behavior data and emotion data of the user, and cause the virtual character to provide information that assists progress of the activities; use a generative AI model to receive, from the user, a prompt sentence that instructs generation of a specific scenario, and generate, based on the prompt sentence, experience scenario data as structured data including environment information, object information, virtual character information, goal information, and interaction rule information; set, based on the experience scenario data generated by the generative AI model, three-dimensional space configuration, physical behavior, path finding, and event control for an execution unit that executes a virtual space simulation, dynamically construct a virtual environment, and encode a simulation result as a time-continuous data sequence; transmit the encoded simulation result and the experience scenario data to a terminal of the user by a streaming method, and cause the terminal to decode and render the simulation result and the experience scenario data so as to present the virtual space to the user in real time; acquire sensor data relating to expressions, voice, and behavior of the user, estimate an emotion state from the sensor data by an emotion estimation function, and dynamically change, in accordance with the emotion state, at least one of the experience scenario data, a configuration of the virtual environment, and the response content of the virtual character by an experience adjustment function; acquire, as input events, movement operations, object operations, and dialogue operations performed by the user in the virtual space, update a progress state of the experience scenario data based on the input events, and generate and transmit, to the generative AI model, an additional prompt sentence including context information comprising the progress state and the input events so that the generative AI model sequentially generates at least one of an answer sentence of the virtual character, hint information, and a new event definition; and reflect the sequentially generated answer sentence, the hint information, and the new event definition in the virtual space simulation, and continuously transmit a result of the virtual space simulation to the terminal by the streaming method so as to provide the user with a dynamically changing experience scenario. This enables improvement of the underlying computer technology by centralizing scenario generation, emotion-aware adaptation, and simulation control on the server-side processor, reducing computation at the terminal, lowering end-to-end interaction latency, maintaining consistent synchronized state across multiple participants, and dynamically tailoring the streamed virtual space to real-time user input and emotional state.

The term “system” refers to a combination of hardware and software components including at least one processor and associated resources that are configured to execute the claimed functions in cooperation.

The term “processor” refers to a hardware execution unit, such as a central processing unit, graphics processing unit, or other computation circuitry, configured to execute instructions that implement the claimed functions.

The term “information processing apparatus” refers to an electronic device, including a server or other computing device, that executes programs to process data and provide interfaces for interaction with a user or a terminal.

The term “terminal” refers to an electronic device operated by a user, including but not limited to a head-mounted display, a wearable device, or a general-purpose computing device, that receives streamed data from the server and presents a virtual space to the user. The term “display interface” refers to a hardware and software combination for visually presenting information to a user, including rendered representations of a virtual space, through displays or optical systems.

The term “input interface” refers to a hardware and software combination for receiving user operations, including signals from controllers, sensors, or user gestures, and converting them into input events for processing.

The term “virtual space” refers to a computer-generated environment distinct from the physical world, defined by digital data specifying spatial structure, objects, characters, and events.

The term “predetermined goal” refers to a target state or objective defined by scenario data, which the user is intended to achieve through activities within the virtual space.

The term “activity” refers to one or more user actions or sequences of actions performed within the virtual space in order to progress toward the predetermined goal.

The term “communication function” refers to a mechanism that enables exchange of data, including position information, operation information, and state information, between the server and multiple terminals in real time.

The term “position information” refers to data representing spatial coordinates, orientation, or posture of a user avatar or object within the virtual space.

The term “operation information” refers to data representing user operations, including movement commands, object manipulations, and dialogue selections, issued through the input interface.

The term “state information” refers to data representing a current status of elements in the virtual space, including object states, character states, scenario progress, and environmental parameters.

The term “virtual character” refers to a software-controlled entity represented within the virtual space, having a visual or symbolic presence, and capable of interacting with the user. The term “artificial intelligence function” refers to computational logic implemented by software models that perform tasks such as reasoning, learning, or natural language processing to generate responses or decisions.

The term “behavior data” refers to data representing user actions or patterns of actions in the virtual space, including movement history, interaction history, and control inputs.

The term “emotion data” refers to data indicative of a user's emotional state, derived from sensor measurements such as facial expressions, voice characteristics, or body movements. The term “response content” refers to information output by a virtual character, including dialogue text, audio responses, gestures, or other expressive actions.

The term “behavior patterns” refers to rules or models defining how a virtual character moves, reacts, and changes state over time in response to inputs or events.

The term “generative AI model” refers to a machine learning model configured to generate new data, such as text or structured scenario data, based on input data including prompt sentences and context information.

The term “prompt sentence” refers to a natural language instruction or request provided by the user, specifying requirements or constraints for generating a particular scenario or content.

The term “experience scenario data” refers to structured data describing a user experience in the virtual space, including environment information, object information, virtual character information, goal information, and interaction rule information.

The term “structured data” refers to data organized in a defined format, such as key-value pairs, records, or hierarchies, enabling programmatic parsing and processing.

The term “environment information” refers to data that defines spatial layout, terrain, architecture, or other environmental attributes of the virtual space.

The term “object information” refers to data specifying properties of items or entities in the virtual space, including type, position, interaction capabilities, and state.

The term “goal information” refers to data describing objectives, sub-objectives, and completion conditions that define the user's targets within the scenario.

The term “interaction rule information” refers to data specifying conditions and effects for interactions between users, objects, and virtual characters in the virtual space. The term “execution unit” refers to a processing subsystem, such as a simulation engine or game engine, configured to execute computations for simulating the virtual space. The term “three-dimensional space configuration” refers to data and parameters defining geometry, spatial relationships, and coordinate systems of objects and regions within the virtual space.

The term “physical behavior” refers to simulated physical phenomena, including movement, collisions, forces, and constraints, applied to objects in the virtual space.

The term “path finding” refers to computation for determining movement routes or navigation paths for entities within the virtual space based on constraints and objectives. The term “event control” refers to logic and parameters that define when and how events in the virtual space are triggered, processed, and terminated.

The term “simulation result” refers to output data generated by the execution unit, including updated positions, states, and visual frames, that represent the evolving virtual space. The term “time-continuous data sequence” refers to a series of data elements, including frames or state updates, ordered in time and representing temporal evolution of the simulation.

The term “encoded simulation result” refers to the simulation result transformed into a compressed or otherwise coded form suitable for efficient transmission.

The term “streaming method” refers to a technique for continuously transmitting data over a network in a manner that allows incremental reception and rendering while later data is still being sent.

The term “sensor data” refers to measurement data acquired from devices such as cameras, microphones, inertial sensors, or physiological sensors, associated with the user.

The term “emotion state” refers to a representation of a user's emotional condition, such as stress level, engagement, or valence, inferred from sensor data.

The term “emotion estimation function” refers to processing logic or a model that analyzes sensor data to infer or classify the emotion state of the user.

The term “experience adjustment function” refers to processing logic that modifies scenario elements, virtual environment configuration, or virtual character responses based on the emotion state.

The term “configuration of the virtual environment” refers to parameters and arrangements defining the structure, appearance, and dynamic properties of the virtual space at a given time.

The term “movement operation” refers to a user input indicating a desired change of position, orientation, or locomotion in the virtual space.

The term “object operation” refers to a user input indicating an interaction with an object, such as selecting, grabbing, activating, or manipulating the object.

The term “dialogue operation” refers to a user input related to communication, such as selecting dialogue options, speaking, or entering text to converse with a virtual character. The term “input event” refers to a unit of information representing a processed user operation that is used by the system to update the virtual space simulation or scenario.

The term “progress state” refers to data indicating a current stage or advancement of the experience scenario, including completed goals, active tasks, and unlocked elements. The term “context information” refers to data describing surrounding conditions relevant to processing by the generative AI model, including the progress state, input events, and other scenario parameters.

The term “answer sentence” refers to text generated by the generative AI model that represents a response or utterance of a virtual character in the context of the scenario. The term “hint information” refers to data that provides guidance, clues, or suggestions to the user for achieving the predetermined goal or progressing in the scenario.

The term “event definition” refers to structured data specifying conditions, triggers, and effects associated with an event to be executed in the virtual space simulation.

The term “virtual space simulation” refers to computation performed by the execution unit to update the state of the virtual space over time according to the scenario data, user inputs, and rules.

The term “dynamically changing experience scenario” refers to an experience scenario in which structure, content, or progression is modified in real time based on user inputs, emotional state, or outputs from the generative AI model.

In one embodiment, a server executes a program that realizes a virtual space experience system as defined in the claims. The server comprises one or more processors, one or more memories, a network interface, and, in some configurations, one or more graphics processing units. The server executes operating system software, middleware, and application software modules that collectively implement scenario generation, virtual space simulation, emotion-aware adaptation, and streaming control.

The server uses a hardware platform that can include a general-purpose central processing unit, such as a multi-core processor based on a common instruction set architecture, and a graphics processing unit dedicated to large-scale matrix operations. The server uses system memory and non-volatile storage to store program instructions and data structures that implement the functions described herein.

The server executes a virtual space simulation engine implemented by a game engine framework. The server uses the game engine framework to manage three-dimensional scene graphs, physics simulations, navigation meshes, and event systems. The server also executes a generative AI model that is implemented as a neural network architecture trained on text and scenario representations. The server, in some embodiments, executes the generative AI model on the graphics processing unit using a deep learning framework such as a tensor operation library.

The server organizes program modules into at least the following functional components: a communication module, a scenario management module, a simulation control module, an emotion analysis module, a generative AI interface module, and a streaming module. Each module manipulates specific data structures and interacts with other modules via defined interfaces in memory.

The server maintains a session data structure for each user. The session data structure includes identifiers, current scenario data, user state, emotional state, and network parameters. The server stores scenario data as structured records, for example, as hierarchical key-value structures that describe environment information, object information, virtual character information, goal information, and interaction rule information. The server stores environment information as a set of region records, each region record containing fields for geometry identifiers, spatial coordinates, and lighting parameters. The server stores object information as records including object type, transform, interaction flags, and state variables.

The server stores virtual character information as records including role identifiers, behavior parameters, and dialogue templates. The server stores goal information as records including completion conditions, reward parameters, and dependency relations among goals. The server stores interaction rule information as condition-action rules referencing objects, virtual characters, and goals.

The server uses a generative AI model to produce new scenario data and dynamic updates. In one embodiment, the generative AI model is implemented as a multi-layer transformer network with an encoder-decoder architecture. The server stores, in memory, model parameters such as weight matrices and bias vectors for each attention layer and feed-forward layer. The server processes a prompt sentence by first converting each token into an embedding vector using a learned embedding matrix. The server then applies multiple attention layers, where each attention layer computes attention logits as scaled dot products between query and key projections of the embeddings, normalizes the logits using a softmax function, and computes weighted sums with value projections. The server then applies position-wise feed-forward networks with nonlinear activation functions to transform the representations.

The server trains the generative AI model offline using scenario corpora and simulated interactions. In training, the server minimizes a loss function that includes a token-level cross-entropy term for predicting the next token, plus additional regularization terms for structural consistency of scenario records. The server updates model weights using gradient descent or a variant such as Adam, where gradients are computed by backpropagation through the transformer layers. The server, during training, uses data augmentation techniques such as paraphrasing of prompt sentences, random shuffling of non-critical scenario elements, and masking of context tokens to improve robustness. Although training is performed prior to deployment, the server can further fine-tune the model using anonymized interaction logs to improve response quality for specific application domains.

The server, during runtime, uses the generative AI model in inference mode. The server constructs an input sequence that concatenates a prompt sentence with context information, such as the current progress state and recent input events. The server encodes context information as textual annotations or as structured tags that the generative AI model has been trained to interpret. The server sets decoding parameters such as temperature, top-k, or top-p thresholds to control diversity of outputs. The server then performs auto-regressive decoding, generating tokens one by one until an end-of-record marker is produced or a maximum length is reached. The server post-processes the generated tokens, parses them into structured scenario data using predefined syntactic markers and schema constraints, and validates the resulting structures against consistency rules.

The server uses prompt sentences to initiate new scenarios and to request incremental updates. In one example, the user inputs the prompt sentence “Please generate a scenario where I explore a medieval castle full of puzzles, and AI-controlled guards give me hints when I get stuck.” In another example, the user inputs the prompt sentence “Generate a cooperative mission in a futuristic city where I and other participants must rescue a scientist, guided by an AI drone.” In another example, the user inputs the prompt sentence “Create a calm forest walk where AI animals react to my voice and lead me to a hidden lake.” The server uses these prompt sentences as starting points for generating coherent and structured scenario data.

The server processes user interactions by maintaining a log of input events. The server represents each input event as a tuple containing an event type, a timestamp, an entity identifier, and parameter values. For example, a movement operation is represented as a tuple containing an operation type field indicating forward movement, a vector for direction, and a magnitude. An object operation is represented as a tuple containing a target object identifier and an operation flag such as grab, open, or activate. A dialogue operation is represented as a tuple containing a selected dialogue option or transcription of user speech.

The server collects sensor data from the terminal. The server receives video, audio, and motion signals that the terminal acquires from sensors such as cameras, microphones, and inertial sensors. The server pre-processes video data by downsampling and cropping facial regions, performs normalization, and extracts feature vectors using a convolutional neural network trained for facial expression recognition. The server pre-processes audio data by computing mel-frequency cepstral coefficients and prosodic features, and then applies a recurrent neural network or transformer-based classifier to infer emotional categories. The server pre-processes motion data by analyzing acceleration and orientation sequences to detect agitation or relaxation patterns. The server combines these modality-specific feature vectors in a fusion layer that outputs an emotion state representation, such as a vector indicating valence, arousal, and dominance. The server then maps this representation into discrete or continuous emotion states that can be used for scenario adjustments.

The server uses the emotion analysis results to modify scenario parameters. The server adjusts difficulty levels, pacing of events, and density of hints by applying predefined mapping functions from emotion state to control variables. For instance, when the emotion state indicates frustration, the server lowers puzzle complexity and increases frequency of hints from virtual characters. When the emotion state indicates boredom, the server increases event frequency or introduces optional challenges. The server accomplishes these adjustments by modifying threshold values in interaction rules, updating goal conditions, or inserting new events into the scenario data structure.

The server manages the virtual space simulation using a simulation control module. The server loads environment information, object information, and virtual character information into the simulation engine. The server configures the scene graph with nodes representing static and dynamic entities, assigns physics colliders and rigid bodies to objects, and builds navigation meshes that specify walkable regions for virtual characters. The server uses a physics engine to advance the simulation, computing object trajectories, resolving collisions, and applying forces according to physical behavior parameters stored in the scenario data. The server uses a navigation system to compute paths for virtual characters based on goal locations and movement constraints.

The server uses a behavior system for virtual characters. The server defines behavior patterns as state machines or behavior trees that reference conditions from behavior data, emotion data, and scenario state. The server updates behavior states at each simulation step, evaluates conditions, and selects actions such as moving to a location, playing an animation, or initiating dialogue with the user. The server modifies behavior parameters dynamically based on outputs from the generative AI model. For example, when the generative AI model produces an answer sentence and an associated action tag indicating “lead user to hidden room,” the server configures the behavior pattern of the virtual character to set a new target in the navigation system and to trigger a guiding animation.

The server encodes simulation results for streaming. The server, in one embodiment, renders the three-dimensional scene into two-dimensional frames using the game engine's rendering pipeline, and then passes these frames to a video encoder implemented by the graphics processing unit. The server compresses the frames using a video compression standard, producing encoded bitstreams suitable for transmission over a network. In another embodiment, the server transmits scene state updates instead of or in addition to encoded frames. The server serializes positions, orientations, animation states, and object states into compact binary messages. This approach can reduce bandwidth usage when terminals perform local rendering.

The server uses a streaming module to transmit encoded simulation results and scenario data to the terminal. The server maintains network sessions using protocols that support low-latency and reliable delivery. The server adjusts bitrate, resolution, and update frequency based on measured network conditions and user device capabilities. By adapting encoding parameters and selectively transmitting only necessary updates, the server reduces communication load while maintaining responsiveness of the system.

The terminal operates as a client device that receives and presents the virtual space. The terminal comprises a processor, a display system, sensors, and a network interface. The terminal executes a client program that establishes a connection with the server, receives streaming data, and performs decoding and rendering. The terminal also executes tracking and input processing modules. The terminal uses inertial sensors and, in some embodiments, cameras to estimate the position and orientation of the user's head and hands. The terminal maps these measurements into pose representations and uses them to control the viewpoint and avatars in the virtual space.

The terminal decodes the incoming simulation results. When the server transmits video frames, the terminal uses a hardware decoder to reconstruct frames and then presents them on displays arranged in a head-mounted configuration. When the server transmits scene state updates, the terminal reconstructs a local scene graph, updates positions and animations of objects, and uses a local rendering pipeline to generate frames. By offloading heavy simulation and scenario generation processes to the server, and limiting the terminal to decoding, lightweight rendering, and sensor processing, the system improves performance on constrained devices and reduces power consumption.

The user interacts with the system by wearing the terminal, observing the virtual space, and operating input devices. The user issues instructions to the generative AI model by entering prompt sentences via a virtual keyboard, voice input, or selection among templates. The user obtains feedback through dialogues with virtual characters, visual cues, and changes in the environment. The user's actions, such as moving toward objects, speaking to characters, or manipulating items, influence the progress state and trigger additional prompt sentences generated by the server.

The server, in some embodiments, generates additional prompt sentences automatically without requiring explicit user input. The server constructs an additional prompt sentence that includes at least one of: a textual summary of recent events, identifiers of active goals, and descriptions of the user's recent behavior. For example, when the user approaches a locked door after failing multiple attempts, the server forms an additional prompt sentence such as “User is standing before a locked door in the castle and has tried to open it several times without success. Generate a hint from a guard character that preserves the puzzle's challenge but reduces frustration.” The server then passes this prompt sentence to the generative AI model, which generates a new dialogue line and possibly updates the scenario rules related to the door.

The server improves computer technology by introducing a unified and adaptive data flow that integrates generative AI outputs into a real-time simulation and streaming pipeline. The server reduces the computational burden on the terminal by centralizing scenario logic, emotion estimation, and simulation on the server, and by transmitting only encoded results and essential state updates. This design reduces redundancy in processing and avoids divergent local scenarios on multiple devices, which improves consistency and synchronization across participants. The server also reduces communication overhead by encoding simulation results efficiently and, where applicable, transmitting only incremental state changes instead of full scene descriptions.

The server achieves improved processing speed and responsiveness by using specialized data structures and non-conventional processing sequences. The server represents scenario data and simulation state in memory in a way that allows direct mapping between generative AI outputs and simulation engine inputs, avoiding costly intermediate conversions. The server maintains indices for objects, regions, and characters, enabling constant-time access for event processing and scenario updates. The server executes emotion analysis and generative inference on the graphics processing unit concurrently with simulation updates on the central processing unit, thereby exploiting parallelism and reducing end-to-end latency. The server further improves accuracy of scenario adaptation and emotional alignment by combining multimodal emotion features and scenario context in the generative AI model inputs. The server does not merely automate human scripting tasks; instead, the server performs high-dimensional pattern recognition and optimization that are not practically achievable through manual rule authoring. The server adjusts parameters such as decoding temperature and repetition penalties dynamically based on user state to maintain coherence and avoid repetitive or irrelevant outputs.

The server applies non-conventional rules and procedures in the processing pipeline. For example, the server imposes structural constraints on generative outputs by inserting control tokens and schema markers, and rejects candidate sequences that violate structural integrity of scenario data. The server uses a custom post-processing algorithm that re-orders or filters events based on simulation feasibility, which is determined by examining the current configuration of the virtual environment and physics constraints. These additional rule-based layers complement the generative AI model and ensure that the resulting scenario updates are technically consistent and computationally efficient.

In another embodiment, the server employs alternative neural network architectures. The server can use recurrent neural networks, convolutional sequence models, or hybrid architectures instead of transformer networks. The server can also incorporate reinforcement learning, where the generative AI model is fine-tuned using feedback signals related to user engagement, latency, or resource usage. In such a case, the server defines a reward function that increases when the user remains engaged, when network bandwidth remains within target thresholds, or when simulation steps are completed within specified time limits. The server then uses policy gradient methods or value-based methods to adjust the generative AI model's parameters so that the model tends to produce scenario updates that reduce computational and communication overhead while maintaining high-quality user experiences. In yet another embodiment, the terminal performs more of the rendering while the server focuses on logic and simulation. The terminal, in this case, receives higher-level instructions such as object transforms and animation triggers, and locally instantiates meshes and textures from a cached asset library. This configuration reduces server-side rendering load and allows the system to scale to more users per server instance. The server still centralizes scenario control and generative AI processing, ensuring that all participants share a consistent scenario state.

Through these embodiments, the server, the terminal, and the user interact in a manner that ties abstract generative processing to concrete control over hardware resources and system performance. The described data structures, algorithms, and processing flows collectively improve the functioning of the computer system as a whole. The system achieves lower latency, more accurate synchronization, and adaptive resource usage, while dynamically generating and updating complex virtual experiences based on prompt sentences and multimodal user data.

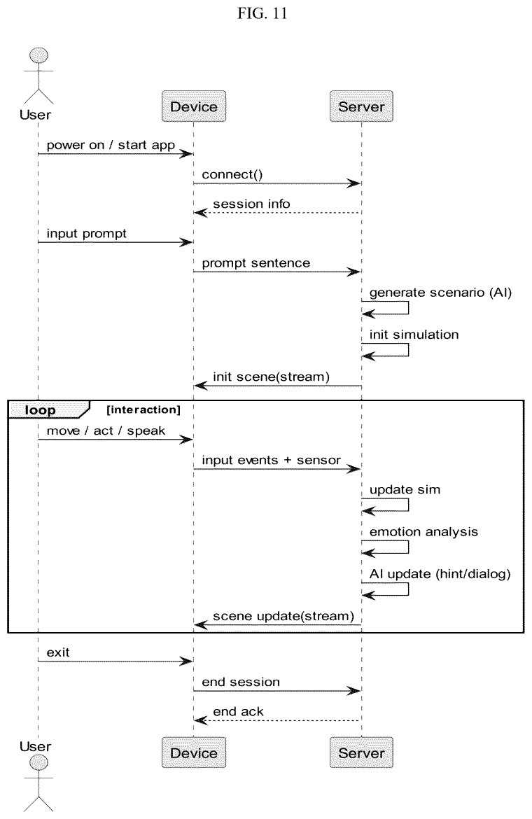

The following describes the processing flow using FIG. 11.

### Step 1

The terminal initializes a connection to the server.

The terminal receives as input local configuration data such as device identifiers, network settings, and user profile information stored in local memory. The terminal processes this data by constructing a connection request message that includes a session initialization header and capability parameters such as supported codecs, display resolution, and available sensors. The terminal outputs the connection request over the network interface toward the server.

### Step 2

The server establishes a session and allocates resources.

The server receives as input the connection request from the terminal. The server parses the request, extracts the device identifiers, capability parameters, and user profile information, and performs authentication by comparing identifiers against records stored in a database. The server then allocates memory for a new session data structure and assigns processor and, when available, graphics processing unit resources for the session. The server outputs a session acknowledgment message containing a session identifier and initial configuration parameters to the terminal.

### Step 3

The terminal prepares the user interface for prompt sentence input.

The terminal receives as input the session acknowledgment message and the associated configuration parameters from the server. The terminal processes these parameters to select appropriate rendering modes and input methods and then instantiates user interface elements such as a virtual keyboard, a voice input widget, or a template selection menu in the virtual view. The terminal outputs display signals to the head-mounted display so that the user can see a prompt input interface.

### Step 4

The user inputs a prompt sentence.

The user receives as input the displayed prompt input interface from the terminal. The user then performs physical actions such as moving hands, pressing controller buttons, or speaking into a microphone to specify a desired scenario. The user, for example, produces a prompt sentence such as “Please generate a scenario where I explore a medieval castle full of puzzles, and AI-controlled guards give me hints when I get stuck.” or “Generate a cooperative mission in a futuristic city where I and other participants must rescue a scientist, guided by an AI drone.” or “Create a calm forest walk where AI animals react to my voice and lead me to a hidden lake.” The user outputs the prompt sentence as text or speech signals to the terminal.

### Step 5

The terminal captures and formats the prompt sentence.

The terminal receives as input user actions and sensor signals representing key presses, controller input, or audio signals. The terminal processes audio signals, if present, by performing speech recognition to convert them into text tokens. The terminal aggregates text tokens into a prompt sentence string and associates the string with the current session identifier. The terminal then constructs a request payload that includes the prompt sentence, language code, and context flags and outputs this payload as a message to the server via a low-latency communication channel.

### Step 6

The server generates initial experience scenario data using the generative AI model. The server receives as input the message containing the prompt sentence and session identifier. The server preprocesses the prompt sentence by tokenizing it into subword units, mapping tokens to embedding vectors using an embedding matrix, and appending special tokens that indicate scenario schema boundaries. The server then forwards the embedded sequence to the generative AI model, which applies multiple attention and feed-forward layers to compute contextualized token representations. The generative AI model decodes these representations auto-regressively to produce an output token sequence representing structured scenario content. The server post-processes the output by parsing schema markers and constructing structured experience scenario data that includes environment records, object records, virtual character records, goal records, and interaction rule records. The server outputs the structured experience scenario data by storing it in the session data structure and by passing it to the simulation control module.

### Step 7

The server configures the virtual space simulation from the generated scenario data. The server receives as input the experience scenario data previously generated by the generative AI model. The server processes environment records to select and load corresponding 3D assets and scene templates into the simulation engine. The server computes three-dimensional space configuration by assigning coordinates, orientations, and scale values to environment segments. The server processes object records to create object instances with associated colliders, physics parameters, and interaction flags. The server processes virtual character records to instantiate character entities and assign behavior parameters and dialogue templates. The server processes goal records and interaction rule records to configure event triggers, completion conditions, and permitted interactions. The server outputs an initialized simulation state loaded into the memory of the simulation engine, ready to be advanced over time.

### Step 8

The server initializes streaming of simulation and scenario information to the terminal. The server receives as input the initialized simulation state and the current network conditions for the session. The server processes the simulation state by producing an initial snapshot that contains scene configuration, object states, and virtual character positions. The server encodes this snapshot either as a rendered video frame using a video encoder or as a serialized state message with compact binary encoding. The server also extracts relevant scenario metadata such as goal descriptions and key locations. The server outputs the encoded snapshot and metadata through the streaming module, which transmits them to the terminal using streaming protocols tuned for low latency.

### Step 9

The terminal decodes and presents the initial virtual environment.

The terminal receives as input the encoded snapshot and scenario metadata from the server. The terminal processes the encoded snapshot by decoding video frames or by deserializing scene state messages into local data structures. When frames are received, the terminal maps them to the displays for each eye. When scene state messages are received, the terminal populates a local scene graph and invokes its rendering pipeline to draw the environment. The terminal also processes scenario metadata to display user interface elements such as a list of goals or a mini-map. The terminal outputs visual signals on the displays and, optionally, audio signals through speakers or headphones to present the initial virtual environment to the user.

### Step 10

The user performs movement, object, and dialogue operations in the virtual space. The user receives as input the presented virtual environment and user interface from the terminal. The user then performs physical actions such as moving the head and body, manipulating controllers, or speaking. These actions represent movement operations, object operations, and dialogue operations. For example, the user may walk toward a castle gate, point at a door handle to attempt opening it, or ask a virtual guard “How can I open this door?” The user outputs these physical actions as sensor signals to the terminal.

### Step 11

The terminal captures user operations and constructs input events.

The terminal receives as input motion sensor data, controller button states, gesture recognition results, and audio signals resulting from the user's physical actions. The terminal processes motion data by estimating head pose and hand pose and by detecting locomotion commands. The terminal processes controller inputs to determine discrete actions such as grab or activate. The terminal, when appropriate, performs speech recognition to convert spoken dialogue into text. The terminal then aggregates these processed signals into structured input events, each including an event type, a timestamp, an entity identifier, and relevant parameters such as direction vectors or selected dialogue text. The terminal outputs these input events to the server over the active communication channel.

### Step 12

The server updates the simulation based on input events.

The server receives as input the structured input events from the terminal. The server processes each event by mapping it to simulation operations. For movement events, the server updates the position and orientation of the user's avatar in the simulation engine, invokes collision checks, and runs navigation updates. For object events, the server evaluates interaction rules associated with the target object to determine whether the action should change the object's state, such as switching a door from locked to open. For dialogue events, the server records the dialogue content and identifies the addressed virtual character. The server updates the progress state of the scenario by checking whether any goals are completed or newly activated. The server outputs an updated simulation state and an updated progress state stored in the session data structure.

### Step 13

The server performs emotion estimation from multimodal sensor data.

The server receives as input sensor data forwarded by the terminal, including facial imagery, voice features, and motion patterns. The server processes facial imagery by running it through a convolutional neural network to extract expression feature vectors, processes voice features by applying a neural classifier to derive prosodic and spectral emotion features, and processes motion patterns by computing statistics that reflect agitation or calmness. The server then concatenates these feature vectors and inputs them to a fusion model that computes an emotion state representation. The server maps the emotion state representation to one or more emotion categories or continuous scores for dimensions such as valence and arousal. The server outputs the estimated emotion state, which is stored in the session data structure and supplied to other modules.

### Step 14

The server adjusts scenario parameters and virtual character behavior based on emotion state. The server receives as input the current emotion state and the progress state. The server processes these inputs by consulting mapping rules or learned policies that relate emotion conditions to changes in scenario parameters. For example, when the emotion state indicates frustration and slow progress, the server reduces puzzle difficulty by modifying threshold values in interaction rules and increases hint frequency from virtual characters by lowering time delays between hints. When the emotion state indicates boredom, the server inserts additional optional events into the scenario data. The server updates behavior parameters for virtual characters, such as making them more proactive in offering assistance. The server outputs modified scenario data and updated behavior parameters, which are applied to the next simulation steps.

### Step 15

The server generates additional content using the generative AI model with context-rich prompt sentences.

The server receives as input the updated progress state, emotion state, and recent input events. The server constructs an additional prompt sentence that summarizes the current situation and requests specific content from the generative AI model. For example, the server may construct a sentence such as “User is standing before a locked door in the castle and has tried to open it several times without success; generate a short hint from a guard character that reduces frustration but keeps the puzzle engaging.” The server tokenizes and embeds this additional prompt sentence along with context tags, and feeds the embeddings to the generative AI model. The generative AI model processes the sequence to produce output tokens representing an answer sentence for a virtual character, optional hint information, and any new event definitions. The server parses the generated token sequence into structured elements and validates them against scenario constraints. The server outputs the generated answer sentence, hint information, and event definitions to the simulation control module.

### Step 16

The server integrates generated content into the virtual space simulation.

The server receives as input the generated answer sentence, hint information, and event definitions. The server attaches the answer sentence to the dialogue queue of the relevant virtual character, updates event schedules or triggers according to the new event definitions, and adjusts goal records when hints indicate changes in goal visibility or priority. The server then advances the simulation, causing the virtual character to move, orient toward the user, and produce the dialogue at the appropriate time according to behavior patterns. The server outputs the updated simulation state, including new animation commands, object state changes, and dialogue events, to the streaming module.

### Step 17

The server encodes updated simulation outputs and streams them to the terminal.

The server receives as input the updated simulation state with new positions, animations, and dialogue cues. The server processes this state by rendering new frames or computing incremental state changes. The server encodes rendered frames using a video encoder or serializes state changes into binary messages optimized for network transmission. The server also embeds dialogue text and hint messages into metadata channels. The server outputs encoded frames and metadata over the streaming channel to the terminal, adjusting bitrate and packet timing according to network feedback to reduce latency and packet loss.

### Step 18

The terminal decodes incoming updates and presents dynamic feedback to the user.

The terminal receives as input encoded frames, state updates, and dialogue metadata from the server. The terminal decodes the video frames, updates its local scene graph with new transforms and animation states, and updates dialogue user interface elements with received answer sentences and hints. The terminal then generates composite images incorporating updated character animations and environmental changes, and, when applicable, renders text or subtitles in the user's field of view. The terminal outputs the visual and audio feedback to the user, enabling the user to perceive dynamic changes in the experience scenario.

### Step 19

The user continues interaction and scenario progression.

The user receives as input the updated virtual environment, including new verbal responses from virtual characters, new visual cues, and adjusted difficulty or pacing. The user reacts by choosing new movement paths, interacting with newly available objects or events, or following hints to advance toward goals. The user's continued actions generate additional sensor signals and input events, which the terminal captures and sends back to the server. The user outputs these actions iteratively, allowing the system to continue the cycle of simulation updates and generative content creation.

### Step 20

The server and terminal terminate the session and release resources.

The server receives as input a termination request from the terminal, which may be generated when the user selects an exit option. The server processes this request by stopping further invocations of the generative AI model for the session, halting the simulation engine instance associated with the session, and releasing allocated memory and compute resources. The server logs final scenario states and performance metrics to persistent storage. The server outputs a termination acknowledgment to the terminal. The terminal receives this acknowledgment as input, processes it by closing network connections, clearing local session data, and returning to a default user interface. The terminal outputs a non-immersive home or system menu display to the user, signaling the end of the virtual space experience.

### Application Example 1

Description follows regarding a flow of the specific processing in an Application Example 1. The units of the system described below are implemented by the data processing device 12 and the smart device 14. The data processing device 12 is called a “server” and the smart device 14 is called a “terminal”.

Conventional virtual environments and online shopping systems typically treat content presentation, user interaction, recommendation logic, and back-end transaction processing as loosely coupled and largely static components. In many implementations, a client device merely renders pre-authored scenes, receives simple user selection events, and forwards these events to a commerce server that operates independently of the immersive experience. Recommendation engines are often based on static rules or batch-processed data, and do not react in real time to fine-grained in-world behavior signals such as gaze, posture, or continuous interaction patterns. Emotion signals derived from facial expressions, voice, or body movement are usually not integrated at all into the rendering pipeline or recommendation logic. As a result, such systems frequently provide a disjointed user experience in which the virtual environment, the recommendation engine, and the commerce back end do not adapt cohesively to the user's current context.

From a computer technology standpoint, this lack of integration leads to several technical problems. First, server resources for three-dimensional scene generation and streaming are not efficiently orchestrated with real-time interaction data, so network and processing resources may be underutilized or misallocated, causing latency, frame drops, or bandwidth waste. Second, recommendation computation generally operates on coarse, delayed data, which prevents the system from exploiting low-level signals such as real-time gaze vectors or micro-interactions that are already captured by the client hardware. Third, emotion estimation, if used at all, is typically processed as an auxiliary analytics function and not as an input that can dynamically reconfigure rendering parameters, virtual entity behavior, or the recommendation surface within the three-dimensional scene. This separation prevents the system from fully leveraging available sensor data to optimize both perceived quality and computational efficiency of the virtual environment.

Furthermore, while generative AI models are capable of producing rich, context-sensitive content, existing systems usually apply such models in an offline or text-only setting. There is no tightly integrated mechanism by which a server can transform real-time interaction and emotion data into structured prompt sentences, feed them to a generative AI model, and immediately reflect the generated output as concrete, machine-interpretable scene updates, scenario branches, or recommendation objects that are encoded and streamed in a format suitable for low-latency rendering on a terminal device. Consequently, the potential of generative AI to drive adaptive scene composition, recommendation layout, and behavior of virtual entities in a resource-constrained, networked three-dimensional environment remains unrealized.

Accordingly, there is a need for an improved computer-implemented system and server-side processing architecture that tightly integrates (i) three-dimensional environment generation and streaming, (ii) fine-grained interaction and emotion sensing, and (iii) generative AI-based scenario and recommendation generation, such that the server can coordinate these components in real time. Such a system should be able to transform multi-modal user data into efficient scene updates and recommendation objects, optimize the usage of computation and network resources, and dynamically adjust the virtual environment, virtual entities, and recommendation presentation based on both user behavior history and estimated emotion states.

The specific processing by the specific processing unit 290 of the data processing device 12 in Application Example 1 is realized by the following means.

The present invention provides a server comprising a processor and a memory storing instructions which, when executed by the processor, cause the server to generate a three-dimensional model of a virtual environment using a three-dimensional development platform, convert the three-dimensional model into streaming data through compression and optimization processing, and sequentially transmit the streaming data to a terminal device of a user; to receive, from the terminal device, interaction data including gaze information, posture information, and operation information captured in real time while the user is immersed in the virtual environment, and to identify, based on the interaction data, a selection of at least one merchandise object within the virtual environment; to query a merchandise information storage unit to obtain attribute information and three-dimensional shape data corresponding to the identified merchandise object, to convert the three-dimensional shape data into a format applicable to a virtual representation of the user, and to generate data representing a virtual trial-use state of the merchandise on the virtual representation for delivery to the terminal device; to receive input indicating a purchase intention of the user, to cooperate with a settlement processing platform to execute payment processing based on the input, to generate order information in accordance with a result of the payment processing, and to cooperate with a delivery management platform to generate delivery information and return the order information and the delivery information to the terminal device; to analyze, by emotion estimation processing, facial information, voice information, and action information of the user so as to estimate an emotion state, and to dynamically modify at least one of virtual environment display parameters, virtual entity control parameters, and recommendation presentation parameters in response to the emotion state; and to generate, by using a generative AI model, user-specific scenario data or merchandise recommendation information based on instruction information including a prompt sentence and on user behavior history data, to map an output of the generative AI model to concrete scene objects and recommendation objects, and to integrate the mapped objects into the streaming data so that the terminal device can render an updated virtual environment reflecting the generated scenario data or the recommendation information in real time. This enables improved computer operation in which server-side scene generation, streaming, recommendation computation, and emotion-aware adaptation are orchestrated as a single pipeline that responds to fine-grained, multi-modal user inputs, thereby reducing latency, efficiently utilizing computation and network bandwidth, and providing a dynamically customized virtual environment and recommendation layout that are technically optimized for the current user behavior and emotion context.

The term “system” refers to an arrangement of one or more information processing devices, storage resources, and communication interfaces that cooperatively execute the functions described herein.

The term “server” refers to an information processing device, or a group of cooperating information processing devices, that executes the main control, data processing, and communication functions of the system, and that provides data and control signals to one or more terminal devices via a communication network.

The term “processor” refers to a hardware computation unit, such as a central processing unit or a graphics processing unit, or a combination thereof, that executes instructions to perform logical operations, numerical calculations, and control flows in the system.

The term “memory” refers to a non-transitory computer-readable storage medium, such as semiconductor memory, magnetic storage, or optical storage, that stores instructions and data for use by the processor.

The term “terminal device” refers to an end-user information processing device, including but not limited to a head-mounted display device, a wearable device, or a general-purpose computing device, that receives streaming data from the server, renders a virtual space, and captures user interaction information.

The term “user” refers to a person or entity that operates the terminal device, enters the virtual space, and provides interaction input, behavioral data, or instruction information to the system.

The term “interface” refers to a combination of hardware and software components, including user interface elements, input handlers, and output presentation modules, that enable the user to access and interact with the virtual space.

The term “virtual space” refers to a computer-generated environment represented in three dimensions or pseudo-three dimensions, in which virtual objects, virtual entities, and user representations are modeled and rendered.

The term “stereoscopic display device” refers to a display apparatus, such as a head-mounted display, that presents left-eye and right-eye images with parallax so as to provide a perception of depth to the user.

The term “activity” refers to a sequence of actions or interactions performed by the user within the virtual space for the purpose of achieving a specific goal.

The term “communication function” refers to a capability of the system to exchange data, including action information and state information, among a plurality of information processing devices via a communication network.

The term “action information” refers to data representing user operations or movements, such as selection events, gestures, navigation, or interaction with virtual objects in the virtual space.

The term “state information” refers to data representing conditions or attributes of the virtual space, virtual objects, virtual entities, or user session, including positions, orientations, statuses, or context indicators.

The term “virtual entity” refers to a computer-generated character or agent placed in the virtual space, which can perform actions or provide information in response to control signals from the server.

The term “artificial-intelligence-based virtual entity” refers to a virtual entity that is controlled by one or more machine learning models or rule-based inference engines so as to respond dynamically to user actions and emotion states.

The term “three-dimensional model” refers to a digital representation of geometric shapes, surfaces, and associated attributes, such as textures and materials, that define the structure of objects or environments in three dimensions.

The term “three-dimensional development platform” refers to a software framework or engine that provides tools and runtime components for constructing, editing, and exporting three-dimensional models and scenes.

The term “streaming data” refers to data that has been encoded and possibly segmented for progressive transmission over a communication network such that the receiving device can start processing and rendering before the entire data set is received.

The term “compression processing” refers to a procedure in which three-dimensional models, textures, or related data are transformed into a reduced-size representation to decrease bandwidth and storage requirements, while allowing reconstruction with acceptable fidelity. The term “optimization processing” refers to a procedure in which three-dimensional data, scene structures, or transmission units are transformed to improve performance characteristics, such as rendering efficiency, memory usage, or network throughput. The term “interaction data” refers to information captured from sensors or input devices of the terminal device, including gaze information, posture information, and operation information that describe how the user interacts with the virtual space.

The term “gaze information” refers to data representing a direction, target, or region within the virtual space at which the user is looking, which may be derived from eye-tracking sensors, head orientation, or equivalent approximations.

The term “posture information” refers to data representing the position and orientation of the user's body or body parts, such as head, hands, or torso, in physical space or in the coordinate system of the virtual space.

The term “operation information” refers to data representing explicit user inputs, such as button presses, touch inputs, gestures, or voice commands, provided through input devices or sensors associated with the terminal device.

The term “merchandise object” refers to a virtual object in the virtual space that represents an item or service that may be inspected, tried, or purchased by the user.

The term “selection content” refers to information indicating which merchandise object or which option associated with a merchandise object has been selected by the user within the virtual space.

The term “merchandise information storage unit” refers to a logical or physical storage component, such as a database, that stores attribute information, three-dimensional shape data, and other information associated with merchandise objects.

The term “attribute information” refers to descriptive data associated with a merchandise object, including but not limited to type, size, color, price, and availability.

The term “three-dimensional shape data” refers to geometric data, such as vertex sets, meshes, or skeletal structures, that define the external form of a merchandise object for rendering in three dimensions.

The term “virtual representation of the user” refers to a computer-generated avatar, model, or proxy that represents the user's body or appearance in the virtual space.

The term “virtual trial-use state” refers to a state in which a merchandise object is virtually applied to or combined with the virtual representation of the user, such that the user can experience how the merchandise appears or behaves as if physically used or worn. The term “purchase intention input” refers to user-provided information indicating a decision to buy a selected merchandise object, including confirmation operations, quantity selections, or option selections.

The term “settlement processing platform” refers to a payment processing infrastructure, including software and external services, that executes financial transaction processing, authorization, and settlement.

The term “consideration processing” refers to processing that determines whether payment for a purchase intention is authorized and completed, including interaction with the settlement processing platform and internal validation.

The term “order information” refers to data that specifies details of a confirmed purchase transaction, including user identification, merchandise identifiers, quantities, prices, and transaction identifiers.

The term “delivery management platform” refers to a logistics or fulfillment infrastructure, including software and external services, that handles shipment preparation, carrier selection, and tracking information generation.

The term “delivery information” refers to data related to shipment of purchased merchandise, including shipping address, carrier information, tracking identifiers, and estimated delivery times.

The term “notification” refers to transmission of information such as order information or delivery information from the server to the terminal device or to another endpoint for presentation to the user.

The term “generative AI model” refers to a machine learning model, such as a neural network, that is configured to generate new data, including text or structured information, based on input data and learned parameters.

The term “prompt sentence” refers to a natural-language or structured text input provided to the generative AI model that specifies instructions, context, or constraints for generating scenario data or recommendation information.

The term “instruction information” refers to data, including at least one prompt sentence and optionally additional parameters, that is used as input to the generative AI model to control or guide content generation.

The term “user behavior history data” refers to accumulated data reflecting past actions and interactions of the user in the virtual space, including viewed merchandise objects, trial-use events, selections, and purchases.

The term “experience scenario data” refers to generated data that defines a sequence of events, interactions, or narrative elements to be presented to the user in the virtual space. The term “recommendation information” refers to data indicating one or more merchandise objects or scenario elements that are suggested to the user, including identifiers, ranking, and explanatory text.

The term “scene object” refers to an individual component in the virtual space, such as a model, light source, UI element, or virtual entity, that is defined by one or more data structures and rendering parameters.

The term “recommendation object” refers to a scene object or associated data structure that visually or interactively presents recommendation information within the virtual space. The term “emotion estimation processing” refers to computational processing that analyzes one or more types of user data, including facial information, voice information, and action information, to infer or classify an emotion state of the user.

The term “facial information” refers to data obtained from sensors or cameras that describe the user's facial features, expressions, or movements.

The term “voice information” refers to audio data representing the user's spoken utterances, tone, or other vocal characteristics.

The term “emotion state” refers to an inferred internal state of the user, such as happiness, frustration, interest, or boredom, derived from emotion estimation processing.

The term “virtual environment display parameters” refers to controllable settings that affect how the virtual space is rendered, including lighting conditions, camera behavior, color schemes, and visual emphasis.

The term “virtual entity control parameters” refers to controllable settings that affect the behavior, dialogue, timing, or animation of a virtual entity in response to user input or emotion state.

The term “recommendation presentation parameters” refers to controllable settings that determine how recommendation information is arranged, prioritized, or visually emphasized in the virtual space.

The term “presentation area” refers to a specified region within the virtual space where recommendation objects or related information are arranged and displayed to the user. The term “predetermined region” refers to a location or zone in the virtual space that is defined in advance or dynamically designated for specific functions such as recommendation display.

The term “real time” refers to operation in which the delay between receipt of input data and presentation of corresponding output data remains within a threshold that allows interactive responsiveness perceived by the user.

In one embodiment, a server, one or more terminals, and a communication network constitute a system that implements the claimed invention. The server includes at least one processor, a main memory, a non-transitory storage device, and a network interface. The terminal includes a processor, a graphics processing unit, a display unit configured as a stereoscopic head-mounted display, one or more sensors such as inertial sensors and cameras, and an input interface such as a controller or hand-tracking module. The user operates the terminal to enter and interact with a three-dimensional virtual space generated and managed by the server.

The server uses a three-dimensional development platform, such as a game engine implementing a scene graph and rendering pipeline, to construct a three-dimensional model of a virtual environment. The server stores base scene assets (meshes, textures, materials, animation clips, navigation meshes) in a structured asset repository, for example in an object storage system or a relational database referencing file paths. The server configures the development platform to load layout data describing a shopping facility, including store areas, shelves, product anchor points, and recommendation zones. The server instantiates prefabricated objects for architectural elements and merchandise placeholders in accordance with the layout data and produces a scene graph that encodes parent-child relationships, transformation matrices, and collision volumes.

The server performs data processing on the three-dimensional model to prepare streaming data for the terminal. The server generates multiple levels of detail for each mesh, performs triangle reduction, and encodes geometry with a mesh compression algorithm. The server compresses textures into a format suitable for mobile graphics hardware and generates a set of binary asset bundles or equivalent container files. The server partitions the scene into spatial chunks and associates each chunk with metadata describing bounding volumes, dependency lists, and streaming priority. By organizing the scene into such structured units, the server can selectively stream only the chunks required by the current user position, thereby reducing network load and client memory consumption.

The terminal receives streaming data from the server through the network interface. The terminal uses a runtime engine capable of interpreting the asset bundles, reconstructing meshes and textures, and updating a local scene graph in main memory. The terminal loads streamed chunks into a graphics pipeline on the graphics processing unit, sets up vertex buffers and index buffers, and binds material and texture resources. The terminal acquires pose information from the sensors, including head orientation and position, and updates a virtual camera in the scene graph based on this pose. The terminal renders stereoscopic images by invoking the rendering pipeline twice per frame, once for each eye position, and outputs the images to the stereoscopic display. The user thus perceives a three-dimensional virtual space that corresponds to the environment constructed by the server.

The user moves physically and uses controllers or hand gestures to navigate and interact with the virtual space. The terminal acquires interaction data comprising gaze information, posture information, and operation information. In one configuration, the terminal calculates a gaze ray from the combination of head orientation, eye-tracking measurements (if available), and a cursor position in the viewport. The terminal computes intersection tests between the gaze ray or controller ray and collider components attached to scene objects that represent merchandise. When the user performs a selection operation, such as a trigger press or gesture, the terminal identifies the target merchandise object and constructs interaction data including a merchandise identifier, user session identifier, interaction type, and timestamp.

The terminal transmits the interaction data to the server over a packet-based protocol. The server parses the interaction data and searches a merchandise information storage unit using the merchandise identifier as a key. The merchandise information storage unit stores attribute information such as category, size, color, and price, together with three-dimensional shape data for each merchandise object. The three-dimensional shape data includes geometry meshes, rigging information, and material parameters for use in virtual trial-on. The server retrieves the corresponding records and, if necessary, converts the shape data into a format compatible with an avatar rig used on the terminal. The server then packages the attribute information and converted shape data into a response message and transmits the message to the terminal.

The terminal receives the attribute information and shape data and updates the virtual space accordingly. The terminal displays a user interface element in the virtual space, such as a product detail panel, showing textual and graphical information derived from the attribute information. The terminal maintains a virtual representation of the user, for example a humanoid avatar with a skeletal rig. The terminal binds the received merchandise shape data to the avatar skeleton by mapping designated attachment points (for example, torso, legs, or feet) and adjusting scale and alignment according to avatar body parameters. The terminal optionally uses a physics simulation module to apply cloth behavior, collision detection, and joint limits, so that the merchandise appears to deform and move naturally in response to avatar motion.

The user can walk around a virtual mirror, rotate the avatar, or change viewing angle using the terminal input interface. The terminal updates the avatar pose, re-runs deformation and lighting calculations on the graphics processing unit, and renders new frames continuously so that the user experiences a real-time virtual trial-use state. By offloading heavy mesh deformation and cloth computation to the graphics processing unit and by limiting scene complexity via streamed level-of-detail models, the system improves rendering performance and reduces frame time, leading to lower motion-to-photon latency compared to naive rendering of full-resolution assets.

When the user decides to purchase the merchandise, the user confirms a purchase intention through an input action on the terminal, such as pressing a virtual purchase button. The terminal sends a purchase intention message to the server, including user identification, merchandise identification, selected options (size, color), quantity, and any discount information. The server validates the message, checks current stock data in an inventory database, and constructs a payment request for a settlement processing platform. The server uses a secure protocol to transmit transaction amount and payment token to the settlement platform, receives the authorization result, and updates an order database with generated order information. The server then invokes a delivery management platform through an application programming interface, providing shipping address and order contents so that shipment can be scheduled and a tracking identifier can be generated. The server returns order information and delivery information to the terminal, which presents a confirmation view to the user in the virtual space.

In addition to deterministic transaction processing, the server processes multi-modal user data to estimate an emotion state. The terminal captures facial information using one or more cameras, captures voice information using a microphone, and captures action information as part of the interaction data. The terminal can pre-encode these signals, for example by extracting facial landmarks, computing mel-frequency cepstral coefficients from audio, and summarizing motion patterns over time windows, and then transmit such feature vectors to the server. Alternatively, the server can receive raw or lightly compressed sensor streams and perform feature extraction.

The server executes an emotion estimation module implemented as a neural network model. In one embodiment, the neural network includes a convolutional sub-network for facial images, a recurrent sub-network for temporal sequences of voice features, and a feed-forward sub-network for aggregated action features. The server concatenates intermediate feature representations and passes them through fully connected layers with non-linear activation functions to obtain an output vector representing probabilities over a set of emotion classes. The server selects the emotion state with the highest probability and optionally maintains a temporal smoothing mechanism to avoid erratic changes.

The server uses the estimated emotion state to adjust technical parameters of the virtual environment. For example, the server modifies lighting profiles, background complexity, or animation frequency embedded in the streaming data to reduce overload when a stress-related emotion state is detected. The server also updates parameters that control the behavior of the virtual entity, such as response delay, dialogue length, or gesture intensity. These adjustments are encoded as parameter updates in the streaming data so that the terminal can efficiently apply them without reloading entire scene assets. By updating only compact parameter sets rather than full models, the system reduces bandwidth usage and avoids excessive state synchronization traffic.

The server further employs a generative AI model to generate user-specific experience scenarios and recommendation information. The generative AI model is, in one example, a transformer-based neural network trained on sequences of tokens representing textual descriptions of fashion items, user profiles, and interaction histories. The server maintains user behavior history data in a structured form, for instance as a sequence of events with attributes such as time, merchandise category, color, and outcome (view, trial, purchase). The server constructs a prompt sentence by combining current context and summarized behavior history. Example prompt sentences include:

“Analyze this user's recent behavior in the virtual clothing store: the user virtually tried on three casual jackets and two pairs of jeans and purchased one pair of black slim-fit jeans. Recommend three additional items, including at least one jacket and one pair of shoes, that match this style, and explain briefly why each item is suitable.”

“Based on this history: the user virtually tried on three navy business suits, two white dress shirts, and one pair of black leather shoes, and purchased one navy suit. Suggest three shirt and tie combinations that complement a navy suit, specifying colors and patterns, and briefly explain the style reasoning.”

The server encodes the prompt sentence into token indices and feeds them into the generative AI model. The model performs multi-head self-attention over the token sequence, computes contextualized embeddings, and outputs a sequence of tokens representing recommended item descriptions and explanations. During training, the server (or an external training apparatus) uses a cross-entropy loss between predicted tokens and ground-truth sequences, and updates model weights via gradient descent with back-propagation. Data augmentation techniques, such as synonym replacement and shuffling of behavior sequences, can be applied to increase robustness.

At inference time, the server applies constrained decoding rules so that the generated text adheres to a pattern suitable for machine parsing. For instance, the server requires that each recommendation line include an item type, a color, and optionally a style adjective. The server parses the generated text using a rule-based parser to extract structured attributes, such as “jacket, dark gray, casual,” and queries the merchandise information storage unit for items matching these attributes. If multiple candidates are found, the server can apply additional ranking rules using metadata such as popularity, inventory levels, and price range. The server maps the selected recommendation items to recommendation objects in the virtual space. The server assigns each item to a presentation area defined in the layout data, for example a “recommended rack” region near the avatar. The server constructs a lightweight representation for each recommendation object, including a reference to an existing merchandise mesh, a position in the virtual environment, and short explanation text derived from the generative AI model's output. The server encodes these recommendation objects as scene update messages and includes them in the streaming data pipeline to the terminal. The terminal then instantiates corresponding objects in its local scene graph and displays them to the user in the designated presentation area.

By integrating the generative AI model into the streaming pipeline in this manner, the server uses the model not merely for offline text generation, but as a component that directly affects real-time scene composition and object placement. The server optimizes the amount of data transmitted by sending only identifiers and incremental scene updates instead of transmitting full regenerated scenes. This reduces network traffic and processing load on both server and terminal and enables the virtual space to adapt to the user's behavior and emotion state with low latency.

The user interacts with the recommendation objects in the same way as with ordinary merchandise objects. When the user selects a recommended item for trial-use, the terminal sends appropriate interaction data to the server, and the above-described merchandise retrieval and virtual trial-use procedures are applied. The server updates behavior history data to reflect this interaction and may generate new prompt sentences capturing the updated context. In this way, the generative AI model and the recommendation surface can be iteratively refined during a session.

In one variation, the server maintains multiple emotion-aware configuration profiles for the virtual environment and applies a decision rule that combines predicted emotion states with explicit user preferences. For example, the server can down-regulate complex particle effects and dense crowds of virtual entities when a high fatigue probability is detected, while maintaining detailed textures for merchandise to avoid degrading evaluation accuracy. The server assigns each parameter set an identifier and streams only the identifier and incremental parameter differences to the terminal. The terminal uses these identifiers to quickly switch between pre-loaded configurations, which reduces the need for full asset reloads and minimizes frame drops. This combination of emotion-aware adaptation and incremental parameter streaming enhances the stability and responsiveness of the computer system as a whole.

In another variation, the server uses separate generative AI models for scenario generation and merchandise recommendation. A first model receives prompt sentences describing desired narrative structures, such as guided tours or cooperative tasks, and outputs scene scripting instructions, while a second model specializes in mapping behavior histories to merchandise attributes. The server can schedule these models on distinct compute nodes or accelerator units, and can prioritize one model over the other based on current resource usage. The server aggregates outputs into a unified set of scene updates, thereby balancing computation load and preserving low response times.

The technical effects of these embodiments are not limited to mere automation of human decision making. The server restructures data flows and computation across multiple modules—scene generation, streaming, interaction analysis, emotion estimation, and generative AI-based recommendation—so that fine-grained sensor data, behavior sequences, and model outputs can be encoded in compact formats aligned with the streaming architecture. By exploiting structured scene chunks, level-of-detail control, and parameter-only updates, the system reduces communication overhead and improves rendering efficiency. By applying multi-modal emotion estimation and transformer-based generative models within a tightly integrated pipeline, the server can adjust virtual environment and recommendation layouts at a temporal resolution and feature granularity that would not be feasible with manual intervention. The causal relationship between these processing strategies and the resulting technical improvements lies in the systematic reduction of data volume transmitted per adaptation, the offloading of heavy computation to specialized hardware in a predictable pattern, and the use of machine-interpretable generative outputs that translate directly into structured scene updates.

Alternative implementations can employ different three-dimensional development platforms, different neural network architectures, or different streaming protocols, as long as the server continues to perform the essential operations of generating and streaming three-dimensional models, acquiring multi-modal interaction and emotion data, invoking a generative AI model with prompt sentences based on user behavior history, and integrating model outputs into the virtual space in a resource-efficient and latency-sensitive manner. The terminal may be a head-mounted display, an augmented reality glasses device, or another stereoscopic display unit with appropriate sensors. The described structures, data flows, and algorithms allow a person skilled in the art to implement the invention in various hardware and software configurations while preserving the improvement in computer technology.

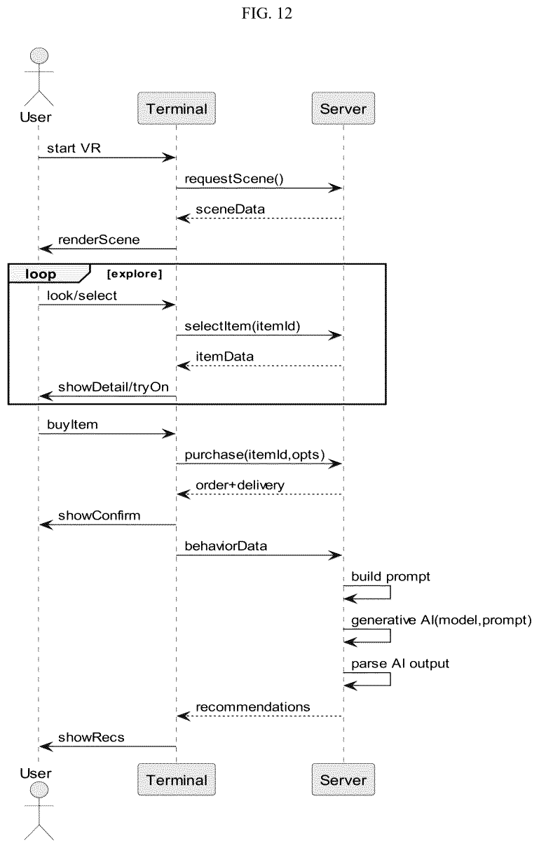

The following describes the processing flow using FIG. 12.

### Step 1

The server initializes a virtual environment model.

The server receives as input layout data describing a virtual facility, asset references for meshes and textures, and configuration parameters for lighting and navigation. The server loads these inputs into a three-dimensional development platform and instantiates scene objects such as walls, floors, shelves, and merchandise anchors. The server constructs a scene graph by computing transformation matrices, parent-child relationships, and collision volumes, and stores this graph in memory as a structured data model. The server outputs an internal three-dimensional scene representation that is ready for optimization and partitioning.

### Step 2

The server prepares streaming data from the virtual environment model.

The server receives as input the internal three-dimensional scene representation created in Step 1. The server applies mesh simplification algorithms to generate multiple levels of detail, performs triangle reduction on high-density meshes, and encodes geometry with a compression algorithm. The server compresses textures into a hardware-compatible format and bundles meshes, textures, and materials into streamable asset containers. The server partitions the scene into spatial chunks based on bounding volumes and assigns metadata such as chunk identifiers and streaming priority. The server outputs a set of optimized, chunked asset bundles and associated metadata suitable for transmission to the terminal.

### Step 3

The terminal requests and receives streaming data for the initial view.

The terminal receives as input a session identifier and an initial scene identifier from the server during session setup. The terminal sends a request to the server specifying the scene identifier and an approximate user position. The server uses this input to select relevant spatial chunks and transmits corresponding asset bundles and metadata over the network. The terminal decodes the received bundles, reconstructs meshes and textures, and builds a local scene graph in memory. The terminal outputs a fully loadable three-dimensional scene segment that can be rendered to the stereoscopic display.

### Step 4

The terminal renders the virtual space and tracks the user.

The terminal receives as input the local scene graph from Step 3 and continuous sensor data from head-mounted sensors and controllers. The terminal uses the sensor data to compute a head pose and controller poses, and updates the virtual camera transform and avatar joints accordingly. The terminal issues draw calls to the graphics processing unit, binding vertex buffers, index buffers, and textures to render left-eye and right-eye images for each frame. The terminal outputs stereoscopic frames to the display and corresponding audio signals to the speakers, allowing the user to perceive and move inside the virtual space in real time.

### Step 5

The user explores the virtual space and focuses on merchandise.

The user receives as input the rendered virtual environment and visual indications of interactable objects, such as highlighted merchandise. The user physically moves, rotates the head, and uses controller buttons or hand gestures to navigate and look at items. Based on this sensory input and personal preference, the user decides to examine a particular merchandise object and directs gaze or a controller ray toward it. The user outputs interaction intent in the form of specific physical movements and input actions that will be captured by the terminal.

### Step 6

The terminal detects merchandise selection from interaction data.

The terminal receives as input continuous sensor readings that include head orientation, gaze direction (if eye tracking is present), controller positions, and button states. The terminal computes one or more rays (for example, a gaze ray and a controller ray) and performs collision detection against colliders associated with merchandise objects in the scene graph. When the user triggers a selection action, such as pressing a button, the terminal identifies the merchandise object whose collider was intersected by the ray at that moment. The terminal constructs interaction data containing the merchandise identifier, user session identifier, interaction type, and timestamp, and outputs a selection event message to the server.

### Step 7

The server retrieves merchandise information and three-dimensional shape data. The server receives as input the selection event message generated in Step 6. The server parses the message to extract the merchandise identifier and session identifier, and validates the session. The server queries a merchandise information storage unit using the merchandise identifier as a key, and retrieves attribute information such as category, available sizes, colors, and pricing, as well as three-dimensional shape data, including meshes and rigging metadata. If the retrieved shape data is in a non-standard format, the server converts it into a runtime format compatible with the avatar rig used on the terminal. The server outputs a merchandise detail response that includes the processed shape data and attribute information.

### Step 8

The terminal presents merchandise details and prepares a virtual trial-use.

The terminal receives as input the merchandise detail response from the server. The terminal parses the attribute information to update a product detail panel in the virtual space, displaying text and icons representing size options, color variants, and price. The terminal loads the three-dimensional shape data into graphics memory, builds a mesh object, and associates material and texture resources. The terminal aligns the merchandise model with a preview pedestal or virtual hanger near the user. The terminal outputs a visible representation of the merchandise and a user interface allowing the user to initiate a trial-use on the virtual representation.

### Step 9

The user initiates a virtual trial-use on the avatar.

The user receives as input the displayed product detail panel and the preview of the merchandise model. The user reviews the available options and decides to try the merchandise on a virtual avatar. The user selects a size and color and activates a trial-use control, such as a virtual button or a gesture. The user outputs a trial-use request via the terminal's input mechanisms, causing corresponding interaction data to be generated.

### Step 10

The terminal applies merchandise data to the virtual representation of the user.

The terminal receives as input the trial-use request and the previously loaded merchandise shape data. The terminal identifies the avatar representing the user and retrieves its skeletal structure and body parameters. The terminal computes a mapping between the merchandise rig and the avatar skeleton, including attachment points and scaling factors. The terminal executes mesh skinning and, optionally, cloth simulation based on joint positions, to deform the merchandise mesh around the avatar body. The terminal updates the scene graph by replacing or overlaying previous clothing meshes with the new merchandise mesh, and outputs an updated avatar state ready for rendering.

### Step 11

The terminal renders the virtual trial-use state for inspection.

The terminal receives as input the updated avatar state from Step 10 and continuous pose data from user movements. The terminal renders the avatar wearing the merchandise from the current camera viewpoint, computing lighting, shadows, and any cloth dynamics on the graphics processing unit each frame. The terminal allows the user to rotate the avatar, change viewing distance, or move around a virtual mirror by interpreting controller inputs and updating camera transforms. The terminal outputs a continuous visual representation of the merchandise on the avatar, enabling the user to inspect the fit and appearance from multiple angles.

### Step 12

The user decides whether to purchase the merchandise.

The user receives as input the rendered trial-use visuals and any auxiliary information such as price and size. The user evaluates the appearance and fit and mentally compares alternatives. Based on this evaluation, the user either accepts or rejects the merchandise. If the user chooses to purchase, the user issues a purchase intention input by selecting a purchase control in the virtual space. If the user declines, the user closes the detail panel or selects a cancel control. The user outputs a clear purchase or non-purchase action that the terminal will encode as an event.

### Step 13

The terminal sends a purchase intention message to the server.

The terminal receives as input the user's purchase confirmation action, including selected size, color, and quantity. The terminal aggregates this data with the current session identifier, merchandise identifier, and any stored user profile data such as shipping preference. The terminal constructs a structured purchase intention message and applies encryption or secure transport settings as required. The terminal outputs this message to the server via a secure communication channel.

### Step 14

The server processes payment and generates order information.

The server receives as input the purchase intention message from Step 13. The server validates the user session and queries an inventory database to confirm stock availability for the selected merchandise and size. The server calculates a total payment amount, including tax and shipping fees, based on configured rules. The server constructs a transaction request for a settlement processing platform, transmitting the amount and a payment token. The settlement platform returns an authorization result, which the server parses to determine success or failure. Based on these computations, the server creates order information including an order identifier, merchandise lines, and payment status, and stores it in an order database. The server outputs an order confirmation response to the terminal and a shipment request to a delivery management platform.

### Step 15

The server generates delivery information and returns it to the terminal.

The server receives as input shipment configuration data from the delivery management platform, including carrier selection and tracking identifier. The server updates the order record with delivery information, such as shipping address, carrier, tracking number, and estimated delivery date. The server constructs a delivery information message that includes these details and associates it with the original session identifier. The server outputs this delivery information to the terminal as part of a final confirmation response.

### Step 16

The terminal displays order and delivery confirmation to the user.

The terminal receives as input the order confirmation response and delivery information from the server. The terminal parses the messages to extract order identifier, merchandise summary, tracking number, and expected delivery time. The terminal generates a confirmation interface in the virtual space, for example a floating receipt panel near the avatar, and populates it with the extracted data. The terminal outputs a visual confirmation of purchase completion and shipment status, allowing the user to review and acknowledge the results.

### Step 17

The server collects and updates user behavior history data.

The server receives as input various interaction events from the terminal throughout the session, including views, trial-use actions, selections, and purchases. The server normalizes these events into a standard format with fields such as timestamp, merchandise category, color, and outcome type. The server appends these records to a behavior history data store associated with the user identifier. The server may aggregate counts, session summaries, and temporal patterns from these raw records and store the aggregated results. The server outputs an updated behavior history dataset that is ready for analysis and recommendation generation.

### Step 18

The server estimates the user's emotion state from multi-modal features.

The server receives as input facial feature vectors, voice feature vectors, and action pattern features either from the terminal or from server-side extraction modules. The server feeds these feature vectors into an emotion estimation neural network that has separate sub-networks for each modality. The server computes intermediate representations using convolutional and recurrent layers, concatenates them, and passes the concatenated vector through fully connected layers to obtain an emotion probability distribution. The server selects a dominant emotion state and optionally applies temporal smoothing by averaging probabilities over a sliding time window. The server outputs an estimated emotion state label and an associated confidence value.

### Step 19

The server generates a prompt sentence for the generative AI model.

The server receives as input the updated behavior history dataset from Step 17 and the current or recent emotion state from Step 18. The server extracts key features from the history, such as frequently tried categories, dominant colors, and recent purchases, and formats these features into human-readable text segments. The server constructs a prompt sentence by combining these text segments with explicit instructions for the generative AI model, for example specifying the number and types of items to recommend and the style of explanation desired. The server outputs a finalized prompt sentence that encodes the user context and desired output pattern.

### Step 20

The server invokes the generative AI model to obtain recommendations or scenarios.

The server receives as input the prompt sentence created in Step 19. The server tokenizes the prompt into discrete tokens and feeds them into a transformer-based generative AI model, which computes contextual embeddings through stacked attention layers and produces an output token sequence. The server decodes the output tokens into text describing recommended items and explanation sentences. The server may apply constraints during decoding, such as limiting vocabulary to certain item types or enforcing structured patterns per line. The server outputs generated text that encodes recommendation information or scenario instructions.

### Step 21

The server converts generated text into structured recommendation objects.

The server receives as input the generated text from Step 20. The server applies a parsing procedure, using pattern matching and rules, to extract item attributes such as category, color, style, and any constraints. The server queries the merchandise information storage unit using these attributes to find concrete items that match or approximate the generated descriptions. The server ranks candidate items by applying additional criteria, such as inventory health and price range, and selects a subset of items to present. The server then constructs structured recommendation objects that contain item identifiers, positions within a presentation area, and short explanation strings. The server outputs a set of recommendation objects ready to be integrated into the virtual space.

### Step 22

The server updates the virtual space with recommendation objects.

The server receives as input the recommendation objects from Step 21 and the current scene state associated with the user's session. The server assigns each recommendation object to a specific presentation area in the layout, such as a recommendation shelf or a floating panel region. The server encodes scene update messages that reference existing mesh templates and textures for the merchandise, along with transforms and UI text bindings for the explanations. The server injects these updates into the streaming pipeline so that only incremental changes are transmitted. The server outputs updated streaming data that, when applied by the terminal, causes new recommendation objects to appear in the virtual space.

### Step 23

The terminal displays recommendation objects and enables further interaction.

The terminal receives as input the incremental scene update messages that include recommendation object definitions. The terminal updates its local scene graph by instantiating new objects at specified positions, attaching corresponding merchandise meshes that are either already cached or newly requested from the server, and binding text components to explanation strings. The terminal renders these objects as part of the next frames so that the user sees a dedicated presentation area populated with recommended merchandise. The terminal outputs an updated visual scene that encourages the user to select and possibly trial-use recommended items, returning the flow to the selection and trial-use steps.

It is also possible to incorporate an emotion engine for estimating the user's emotions. That is, the specific processing unit 290 may estimate the user's emotions using an emotion identification model 59, and perform specific processing based on the estimated emotions.

### Example 2

Description follows regarding a flow of the specific processing in an Example 2. The units of the system described below are implemented by the data processing device 12 and the smart device 14. The data processing device 12 is called a “server” and the smart device 14 is called a “terminal”.

Conventional computer-implemented virtual environments typically handle world state management, real-time communication, and automated assistance as separate and loosely coupled subsystems. For example, a common configuration uses one system for rendering and simulation of a virtual environment, a separate messaging subsystem for text and voice communication among users, and an additional, external recommendation or chatbot service that does not possess a consistent view of the real-time environment state. In such configurations, the communication subsystem generally treats messages as opaque text or audio streams without semantic integration into the virtual environment state, and any automated assistance is often limited to static scripts or rule-based responses unrelated to the current objective or progress of the user.

As a result, the underlying computer system does not efficiently utilize runtime context, such as the ongoing objective, participant configuration, recent user actions, or current communication activity, when generating machine-generated proposals. The generative AI model, if present, frequently operates on decontextualized prompt sentences that do not reflect the continuous evolution of the virtual environment and the session state. This leads to suboptimal guidance, redundant or irrelevant proposals, and increases the cognitive load on the user, who must manually reconcile AI output with the actual state of the virtual environment and current collaboration status.

Furthermore, existing architectures do not provide an integrated session management mechanism that jointly supervises text communication, voice communication, and AI response acquisition, nor do they dynamically adapt the user interface and in-world presentation based on these multi-channel states. In many cases, the system treats failures or delays in one channel (for example, voice connection loss or delayed AI response) as isolated events, without adjusting the overall user experience or fall-back paths, resulting in fragmented interaction flows and degraded system responsiveness from the user's perspective.

In addition, conventional systems rarely maintain and exploit a structured history of user inputs, actions, and prior AI responses as first-class data that can be reused to condition subsequent AI calls. Even where partial logging exists, the logs are often stored passively and not actively supplied to the generative AI model as part of a unified context. This prevents the system from leveraging accumulated dialogue context and behavioral history to generate more coherent, goal-oriented proposals and limits the ability of the computer system to improve its own effectiveness over time for ongoing sessions.

Accordingly, there is a need for an improved computer-implemented system and server architecture that tightly integrates virtual environment state management, real-time communication control, and interaction with a generative AI model, in such a way that contextual information (including environment state, communication state, and historical interaction data) is used as a primary resource for generating and presenting proposals. Such a system should provide integrated session management across text, audio, and AI channels, and should dynamically adjust the virtual environment presentation and user interface based on these combined states, thereby improving the technical performance and responsiveness of the computer system in delivering context-aware assistance and coordinated collaboration support.

The specific processing by the specific processing unit 290 of the data processing device 12 in Example 2 is realized by the following means.

The present invention provides a server comprising a processor configured to manage environment state data for a virtual environment including position information, object information, participant information, and information on an ongoing objective; to update, in an authoritative manner, a state of the virtual environment based on the environment state data and to transmit update results to user terminals; to control establishment of communication paths with the user terminals and to transmit and receive, in real time, multiple types of communication data including character information and audio information so as to enable information sharing and cooperative work among users; to perform context analysis to extract context information relating to an objective that a user attempts to achieve in the virtual environment and to a progress state from character input, audio input, or operation input received from a user terminal; to perform cooperation with a generative AI model by querying the generative AI model using, as input data, the context information and a prompt sentence received from the user as an instruction sentence to the generative AI model and by causing the generative AI model to generate response data including proposal information for achieving the objective based on the prompt sentence and the context information; to perform proposal presentation control by formatting the response data acquired from the generative AI model in association with the ongoing objective, a participant configuration, and a communication state in the virtual environment, transmitting the formatted response data as the proposal information to the user terminal, and presenting to the user a next action candidate or a cooperation method; and to perform integrated session management by integrally managing a transmission and reception state of the character information, a transmission and reception state of the audio information, and a response acquisition state from the generative AI model and dynamically switching display content and a user interface in the virtual environment according to these states. This enables the computer system to operate as a unified, context-aware interaction platform in which virtual environment control, multi-channel communication, and generative AI-based proposal generation are tightly integrated, thereby improving responsiveness, reducing fragmentation between subsystems, and enhancing the technical performance of the system in delivering real-time, goal-oriented guidance and collaboration support to users.

The term “system” refers to a combination of hardware and software components including at least one processor and one or more terminals that cooperate to provide a virtual environment, communication functions, and generative AI-based proposal functions to users. The term “processor” refers to one or more hardware processing units, such as a central processing unit or a processing core, that execute computer-readable instructions to perform the functions described in the claims.

The term “user” refers to an individual or entity that accesses the system through a terminal and participates in activities within a virtual environment.

The term “user terminal” refers to an electronic apparatus operated by a user, such as a computing device equipped with a display, an input device, and a communication interface, that exchanges data with the processor and presents a user interface.

The term “virtual environment” refers to a computer-generated space represented by digital data, in which users can perceive, via a user terminal, one or more scenes, objects, and participants, and can perform activities toward one or more objectives.

The term “objective” refers to a goal, task, or target state that a user attempts to achieve within the virtual environment.

The term “activity” refers to a sequence of user operations, system responses, and interactions with other users or objects that are performed in the virtual environment in order to progress toward an objective.

The term “interface” refers to a set of graphical or other interaction elements, including screens, controls, and input fields, through which the user views information and provides input to the system.

The term “display content” refers to visual information, including graphical elements, text, icons, and indicators, that is generated by the processor and presented on a display of the user terminal.

The term “user interface” refers to a configuration of interactive elements, such as menus, buttons, panels, and input areas, that are displayed on the user terminal and that enable the user to operate the system.

The term “communication path” refers to a logical or physical connection established between the processor and one or more user terminals for transmitting and receiving communication data.

The term “communication data” refers to data transmitted between the processor and user terminals for communication among users, including at least character information and audio information.

The term “character information” refers to data representing text, symbols, or other alphanumeric content used for messaging or display in the virtual environment. The term “audio information” refers to data representing sound, including voice signals captured from users and audio output played back to users.

The term “information sharing” refers to an operation in which communication data is transmitted and made available to multiple users so that each of the multiple users can perceive the same content.

The term “cooperative work” refers to joint activities performed by multiple users in the virtual environment, in which users share information, coordinate tasks, or perform actions that contribute to an objective.

The term “environment state data” refers to structured data representing a current state of the virtual environment, including at least position information, object information, participant information, and information on an ongoing objective.

The term “position information” refers to data indicating locations and orientations of one or more entities, such as users or objects, within a coordinate system of the virtual environment. The term “object information” refers to data that defines properties, types, identifiers, and statuses of entities other than users within the virtual environment.

The term “participant information” refers to data representing users who are currently associated with or present in the virtual environment, including identifiers and optionally roles or attributes.

The term “ongoing objective” refers to an objective that is currently active or in progress for a user or a group of users within the virtual environment.

The term “update result” refers to data indicating a change or new value of the environment state data after the processor has updated the state of the virtual environment.

The term “context analysis” refers to a processing operation in which the processor interprets inputs, including character input, audio input, or operation input, to derive context information related to an objective and a progress state.

The term “context information” refers to data describing a situational state surrounding a user's objective and progress in the virtual environment, including elements such as current tasks, recent actions, and relevant environment state.

The term “character input” refers to text or symbolic data entered by a user through an input device of a user terminal.

The term “audio input” refers to sound data, including voice utterances, captured by a user terminal and transmitted to the processor.

The term “operation input” refers to control signals generated by user actions such as clicking, touching, or operating keys or controllers that affect the virtual environment or the user interface.

The term “generative AI model” refers to a machine learning model, such as a neural network model, configured to generate output data including text proposals based on input data including prompt sentences and context information.

The term “prompt sentence” refers to an instruction or query expressed in natural language that is provided by a user as input to the generative AI model.

The term “instruction sentence” refers to a prompt sentence that explicitly or implicitly indicates a request for the generative AI model to generate specific information or proposals.

The term “response data” refers to data output by the generative AI model in response to an input including a prompt sentence and context information, the data including at least proposal information.

The term “proposal information” refers to information that suggests one or more actions, strategies, or cooperation methods to the user in order to achieve an objective in the virtual environment.

The term “proposal presentation control” refers to a processing operation in which the processor formats response data from the generative AI model, associates the response data with environment and communication states, and transmits and presents the resulting proposal information to the user.

The term “participant configuration” refers to a current composition, number, and attributes of users participating in a given virtual environment or session.

The term “communication state” refers to a state of one or more communication channels, including text and audio channels, such as being active, idle, interrupted, or degraded.

The term “next action candidate” refers to a suggested subsequent operation or activity that a user may perform in order to make progress toward an objective.

The term “cooperation method” refers to a suggested way in which multiple users can coordinate or divide tasks to achieve an objective.

The term “integrated session management” refers to a processing operation in which the processor supervises and coordinates multiple communication and AI interaction channels within a single session, including text, audio, and AI response channels, and adjusts the system behavior accordingly.

The term “transmission and reception state” refers to a condition indicating whether data for a particular communication type, such as character information or audio information, is being successfully transmitted and received, delayed, or failed.

The term “response acquisition state” refers to a condition indicating whether a response from the generative AI model has been requested, is pending, has been successfully acquired, or has failed.

The term “virtual reality technology” refers to a computer technology that generates immersive three-dimensional or panoramic content, typically displayed through head-mounted or similar displays, to represent a virtual environment to a user.

The term “augmented reality technology” refers to a computer technology that overlays virtual content onto imagery or perception of a physical environment so that the virtual content appears to coexist with the physical environment.

The term “image information” refers to data representing one or more images or frames, which may include two-dimensional or three-dimensional graphics used for visualization of the virtual environment.

The term “immersive experience” refers to a user experience in which a user perceives a high level of presence or engagement in the virtual environment, supported by visual and possibly other sensory cues.

The term “history data” refers to accumulated records of past interactions, including at least user character input history, user audio input history, user action history, and past response history of the generative AI model.

The term “character input history” refers to a log of previous character inputs that the user has provided through the system over time.

The term “audio input history” refers to a log of previous audio inputs, including speech or other sounds, that the user has provided through the system over time.

The term “action history” refers to a log of previous actions taken by the user in the virtual environment, including movement, object interactions, and interface operations. The term “past response history” refers to a log of previous outputs generated by the generative AI model in response to earlier prompt sentences.

The term “history cooperation processing” refers to a processing operation in which the processor supplies history data to the generative AI model together with a current prompt sentence to generate proposal information that reflects continuous dialogue context and past behavior.

The term “continuous dialogue context” refers to a state of an interaction that spans multiple exchanges between the user and the generative AI model, in which earlier prompts and responses influence later outputs.

In one embodiment, a server provides a virtual environment platform that integrates environment state management, multi-channel communication, and interaction with a generative AI model. The server includes at least one processor, a main memory, a nonvolatile storage device, and a network interface, and executes a program stored on a computer-readable storage medium. The program is implemented, for example, using an operating system such as a general-purpose server operating system, an application framework such as a web application framework, and middleware modules for communication, database access, and AI model invocation.

The server uses hardware such as a multi-core central processing unit, a volatile memory device such as random-access memory, a nonvolatile storage device such as a solid-state drive, and a network interface controller to perform the described operations. In some embodiments, the server further uses an accelerator such as a graphics processing unit to execute computations related to a generative AI model. The server executes software modules including a web server, an application server, a database management system, and an AI inference engine, which can be implemented by commonly available frameworks and libraries.

The terminal is a computing device operated by a user. The terminal includes a processor, a display, a user input device such as a keyboard, a pointing device, or a touch panel, an audio input device such as a microphone, an audio output device such as a speaker or headphone interface, and a network interface. The terminal executes client software such as a web browser, a native application, or a hybrid application. The terminal uses standard rendering technologies such as two-dimensional graphics or three-dimensional graphics, and, in some embodiments, uses a graphics library such as a web-based three-dimensional graphics library to render the virtual environment.

The user operates the terminal to connect to the server over a communication network. The user views the virtual environment on the display of the terminal and provides input via the user input device and the microphone. The user receives text information, audio information, and proposal information delivered from the server, and performs actions in the virtual environment in response to these outputs.

The server manages environment state data in the main memory and in the storage device. The environment state data is stored as structured records that include at least position information of user avatars and virtual objects, object information describing properties of entities in the environment, participant information describing users that are associated with a given virtual environment instance, and information representing an ongoing objective for a particular session or group. The server stores environment state data using data structures such as associative arrays, lists, and graph structures, and persists relevant portions to a relational database using tables with fields for identifiers, coordinates, state flags, and timestamps.

The server executes environment state update processing by applying deterministic algorithms to the environment state data. The server calculates new positions and states of entities based on user inputs, time evolution, and interaction rules. For example, the server uses numerical computation routines for coordinate updates, collision detection functions for object interaction, and rule evaluation logic for transitions of objective states. The server computes these updates using the processor and stores the results back into the environment state data, then transmits the updated state fragments to one or more terminals via a communication protocol such as a bidirectional message channel. By centralizing and structuring environment state updates, the server reduces inconsistent client-side computations and thereby improves data integrity and synchronization performance across terminals.

The server controls communication with terminals by maintaining logical communication paths for text and audio channels. The server receives character information as structured messages from the terminals and routes the messages to appropriate destinations based on room identifiers and participant information. The server stores text messages in a database table with fields for message content, sender identifier, channel identifier, and time of transmission. The server also manages audio information by coordinating real-time media connections between terminals. In one embodiment, the server uses a media communication framework to handle session descriptions, network traversal, and selective forwarding of audio streams. The server manages per-participant audio stream metadata and uses this metadata to control which streams are forwarded to which terminals in order to reduce unnecessary network traffic and processing load.

The server performs context analysis by processing character input, audio input, and operation input received from the terminal. The server applies a pipeline of text and signal processing steps to derive context information representing the user's objective, current progress, and environment-related constraints. For character input, the server performs tokenization, part-of-speech tagging, and keyword extraction using natural language processing algorithms implemented in software libraries. For audio input, the server optionally converts audio signals into text using speech recognition algorithms, then applies similar text processing. For operation input, the server interprets control commands such as movement, object interaction, and interface actions, and stores these as structured events in an action log.

The server then aggregates these processed inputs into context information. The context information can be represented as a structured object that includes fields such as current objective identifier, current subtask identifiers, recent actions within a defined time window, current participants, and recent communication summaries. The server may apply weighting or filtering algorithms when composing the context information, for example by emphasizing more recent events and de-emphasizing older events, in order to keep the context set compact and relevant. By constructing context information in this structured manner, the server reduces the amount of raw data supplied to subsequent computation stages and improves the efficiency of downstream AI processing.

The server interacts with a generative AI model by constructing input sequences for the model from the context information and a prompt sentence received from the user. The generative AI model is, in one embodiment, a transformer-based neural network that has multiple layers of self-attention and feedforward sublayers. The model uses an input embedding layer to convert tokens into vectors, multiple transformer blocks to perform attention-based aggregation of information across tokens, and an output layer to generate probability distributions over candidate tokens.

The server represents the prompt sentence as a text string, for example:

“What should I do next to successfully complete the team mission in this virtual room?” “Please suggest how I can coordinate more efficiently with my teammates using the chat and voice features here.”

“Give me a step-by-step plan to solve the current puzzle in this virtual environment.” “Summarize the key points from today's discussion in this virtual space so I can assign tasks clearly.”

The server concatenates the prompt sentence with a textual representation of the context information, or encodes the context information into additional tokens, and sends the resulting input sequence to the generative AI model. The generative AI model includes parameters such as attention heads, layer dimensions, and activation functions. During inference, the model performs matrix multiplications between the input embeddings and learned weight matrices, computes attention scores between token pairs, and updates token representations accordingly. The generative AI model then computes an output token distribution for each time step and sequentially selects tokens until an end condition is met. The server executes the generative AI model either locally or through an AI inference service. When executed locally, the server uses a specialized inference engine running on a processor and, optionally, a graphics processing unit. The server loads pre-trained model parameters from storage into memory. The server then applies a deterministic decoding algorithm such as greedy decoding, top-k sampling, or nucleus sampling with specified hyperparameters to produce the output text. When executed through a remote AI service, the server transmits the encoded input sequence and hyperparameters over a secure network protocol, and then receives the generated text as a response.

The server performs response post-processing by parsing the generated text into proposal information suitable for use within the virtual environment. The server may segment the generated text into bullet points, steps, or separate recommendations. The server maps references in the generated text to actual entities in the environment state data, for instance by linking mentions of “team members” to the participant information records. The server also applies safety or policy filters, implemented as rule-based or statistical classifiers, to remove or modify undesirable content. The server then formats the proposal information as structured data that includes fields such as proposal type, target entity, suggested action, and priority. The server performs proposal presentation control by associating the formatted proposal information with the ongoing objective, participant configuration, and communication state. The server selects appropriate presentation channels and user interface elements based on this association. For example, when a proposal suggests a next action step for a particular user, the server may transmit a customized notification to the terminal of that user and highlight a relevant object or location in the virtual environment. When a proposal suggests a cooperative method, such as organizing a voice meeting, the server may automatically open a panel in the user interface that allows the user to start or join a voice channel. By coupling the proposal information with concrete user interface actions and environment updates, the server ensures that the generative AI output is not merely displayed as static text but is integrated into the operational control of the virtual environment.

The server performs integrated session management by maintaining a unified session record for each ongoing virtual environment session. The session record includes the transmission and reception state of character information, the transmission and reception state of audio information, and the response acquisition state from the generative AI model. The server stores these states in data structures such as state flags, counters, and timestamps. The server monitors these states and triggers state transitions when events occur, such as a disconnection of an audio stream, a backlog of text messages, or a delay in receiving an AI response. The server dynamically switches display content and the user interface in the virtual environment according to the session states. For example, when the server detects a degraded audio channel, the server may instruct terminals to emphasize text communication panels and display warnings or alternative options. When the server detects that an AI response is delayed, the server may display a progress indicator and propose fallback actions based on cached or previously generated proposals. This integrated session management coordinates multiple subsystems and minimizes the impact of partial failures on the overall user experience, leading to a more robust and technically efficient system operation.

The server further maintains history data for each user and each session. The history data includes character input history, audio input history, action history, and past response history from the generative AI model. The server stores the history data in a database with indexing by user identifier and session identifier, and uses compression or summarization techniques to limit the storage size. For example, the server may store vector embeddings of past messages instead of raw texts, or may store action sequences as parameters of a behavioral model. The server retrieves the relevant history data when constructing new inputs for the generative AI model. By providing prior inputs and outputs along with the current prompt sentence, the server enables the model to generate proposals that reflect continuous dialogue context and previously taken actions.

The server uses nontrivial algorithms to select and compress the history data supplied to the generative AI model. The server may apply attention score estimation, recency-based pruning, or topic clustering to determine which historical elements are most relevant to the current context. These operations involve computing similarity measures between embeddings of textual segments or action sequences, which are generated by a separate encoder model or by the same generative AI model in an encoding mode. The server then composes a condensed context window that fits within the input length constraints of the generative AI model while preserving important information. This selection and compression process reduces the computational load of the model and improves the relevance and coherence of the generated proposals, yielding a technical improvement in model usage efficiency.

The generative AI model itself is trained, in one embodiment, by supervised learning on paired input-output examples and fine-tuned by reinforcement learning from human or synthetic feedback. The model parameters are updated by gradient-based optimization algorithms such as stochastic gradient descent or an adaptive optimizer. During training, the model uses a loss function such as cross-entropy between predicted token distributions and target tokens. The server, or an associated training platform, iteratively updates the weight matrices by computing gradients via backpropagation, adjusting the parameters to minimize the loss. In some embodiments, data augmentation techniques are used, such as paraphrasing prompt sentences or shuffling context elements, to increase robustness. By training the model on virtual environment-related contexts and proposals, the system achieves improved precision and stability when generating proposals tailored to the described environment and session structures.

The system provides technical effects beyond mere automation of human tasks. By integrating environment state data, communication state data, and AI interaction into unified data structures and algorithms, the server reduces redundant data transfers between subsystems, minimizes inconsistent environment states, and improves cache locality in memory. The use of structured context information and compressed history data reduces the number of tokens supplied to the generative AI model while maintaining relevant information, which decreases inference time and network bandwidth consumption. The integrated session management logic reduces error conditions and recovery time by proactively adjusting user interface states and communication modes in response to channel degradations, thereby improving system-level reliability.

The terminal benefits from reduced rendering and communication overhead by receiving pre-processed, context-aware guidance from the server. The terminal does not need to execute heavy inference or complex environment logic, which allows devices with limited resources to participate in the virtual environment. By offloading heavy computation to the server and by using structured update data, the terminal reduces redundant local computation and can focus on efficient rendering and input handling.

The user benefits from more accurate, contextually aligned proposals and a smoother collaboration experience. However, the technical improvement lies primarily in how the server uses data structures and algorithms to coordinate multiple subsystems and how it controls the flow of information between the virtual environment engine, the communication engine, and the generative AI model. These mechanisms increase processing speed, lower communication load, and improve the precision of proposal information and environment synchronization, which are measurable improvements in computer system performance. In an alternative embodiment, the server uses different types of generative AI models, such as recurrent neural networks or encoder-decoder architectures, instead of or in addition to transformer-based models. The server may also employ hybrid models that combine rule-based logic with neural network outputs, for example by constraining the proposals to follow certain environment constraints or action schemas. The server may further provide different modes of context analysis, such as focusing only on recent speech data for voice-based queries, or emphasizing long-term action patterns for strategic planning proposals. In another embodiment, the terminal is a head-mounted display device that provides virtual reality or augmented reality output. In this case, the server generates image information that includes stereoscopic views or overlays of virtual objects onto real-world imagery. The terminal renders this image information and uses sensor data, such as head pose and spatial mapping data, to align the display with the user's movements. The server uses environment state data to determine the spatial placement and behavior of virtual elements corresponding to the proposal information, such as highlighting a virtual object or path suggested by the generative AI model. This configuration demonstrates that the system controls specific hardware outputs and sensor-based rendering, which further anchors the invention in concrete computer technology.

In yet another embodiment, the server deploys multiple distributed instances for scalability. Each instance manages a subset of virtual environment sessions and shares summary state data using a distributed data store. The generative AI model may run on a dedicated inference cluster, with the server nodes sending context information through a message queue. The distributed architecture uses consistent hashing or load-balancing algorithms to allocate sessions to server instances. This architecture distributes computation load and reduces latency, improving the practicality of the system for large-scale deployments.

The system therefore provides a concrete, technical implementation in which the server, the terminal, and the generative AI model cooperate to manage environment state, communication, and context-aware proposal generation in a manner that improves processing efficiency, synchronization, and guidance precision, rather than merely automating a human cognitive process.

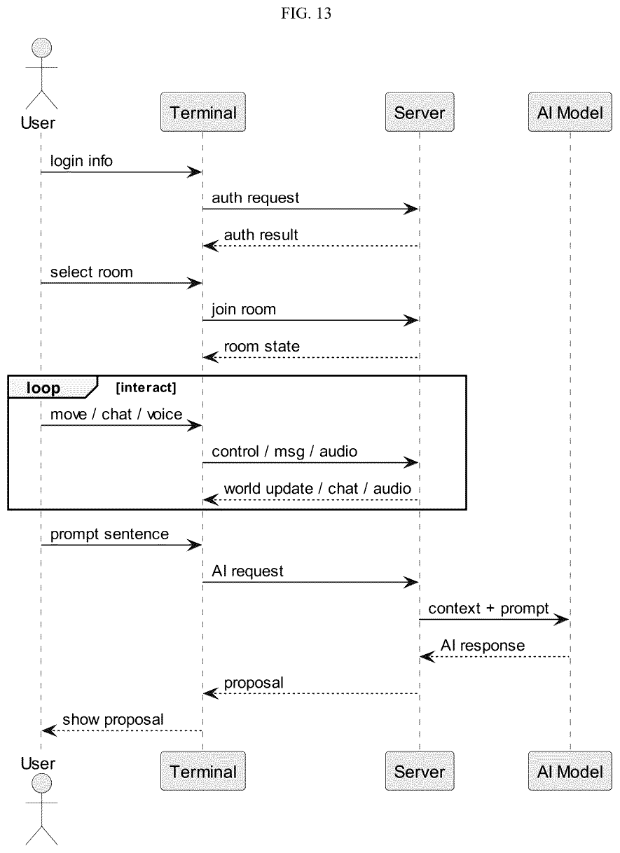

The following describes the processing flow using FIG. 13.

### Step 1

User operates the terminal to start a session with the server. User inputs identification information such as a user ID and a password into an authentication screen displayed by the terminal. Terminal takes, as input, the user ID and password entered via a keyboard or a touch interface, and generates, as output, an authentication request message that includes the user ID and a hashed or encrypted form of the password. Terminal sends this authentication request to the server over a secure communication channel.

### Step 2

Server receives the authentication request from the terminal. Server takes, as input, the user ID and password hash contained in the request, and performs a data lookup operation on a user account table stored in a database. Server executes a comparison operation between the received password hash and a stored password hash for the corresponding user record. Based on this comparison, server generates, as output, either an authentication success response containing a session token and user profile data or an authentication failure response. Server transmits the response to the terminal.

### Step 3

Terminal receives the authentication response from the server. Terminal takes, as input, the response containing the session token and user profile data, and stores the session token in a secure storage area such as a protected memory region or browser storage with security attributes. Terminal generates, as output, an updated user interface state that grants access to a virtual environment selection screen, and displays a list of available virtual environments or rooms on the display.

### Step 4

User selects a virtual environment or room in which to participate. User inputs a selection command by clicking or tapping on an item in the list displayed by the terminal. Terminal takes, as input, the selected room identifier and the stored session token, and generates, as output, a room join request message that includes the room identifier, user identifier, and session token. Terminal sends this room join request to the server over a persistent communication channel such as a bidirectional message channel.

### Step 5

Server receives the room join request from the terminal. Server takes, as input, the room identifier, user identifier, and session token, and performs a verification operation on the session token using a session management module. Server then performs a data lookup operation on environment state data to retrieve the current state associated with the specified room, including object positions, participant list, and ongoing objective information. Server generates, as output, an initial environment state package that encapsulates these elements, and sends this package to the terminal.

### Step 6

Terminal receives the initial environment state package. Terminal takes, as input, structured data describing object positions, participant information, and ongoing objective information, and performs data parsing and mapping operations to convert this structured data into internal client-side objects and scene graph nodes. Terminal uses a rendering engine to compute, as output, drawing commands that render a graphical representation of the virtual environment on the display. Terminal presents to the user an initial view of the virtual environment, including visible objects and participant indicators.

### Step 7

User interacts with the virtual environment by operating input devices. User may perform actions such as moving an avatar, selecting an object, or opening a communication panel. Terminal takes, as input, low-level events from devices such as keyboard keypresses, mouse movements, touch gestures, or controller signals, and translates these into higher-level control commands such as “move forward,” “rotate,” or “select object.” Terminal generates, as output, control messages that encode these commands with attributes such as magnitude, direction, and target object identifier, and transmits the control messages to the server.

### Step 8

Server receives control messages from multiple terminals. Server takes, as input, a set of control messages each associated with a particular user and environment instance, and executes environment update algorithms that modify environment state data. Server performs data processing operations such as kinematic calculations for updated positions, collision detection between objects, and rule-based state transitions for interactive entities or objective progress. Server generates, as output, updated environment state fragments that describe new positions, changed object states, and updated objective status, and broadcasts these fragments to all terminals participating in the same virtual environment.

### Step 9

Terminal receives updated environment state fragments from the server. Terminal takes, as input, the updated positions and statuses of objects and participants, and performs a data merge operation that updates the locally stored scene objects with new attribute values. Terminal uses a graphics pipeline to recalculate object transforms, visibility, and animations. Terminal generates, as output, a new frame to be displayed, and renders the new frame so that the user sees synchronized changes in the virtual environment.

### Step 10

User initiates text communication with other participants. User opens a chat panel on the terminal and inputs a message such as “Let's divide the tasks.” Terminal takes, as input, the character string entered in the chat input field and the identifier of the selected chat channel or room. Terminal performs data encapsulation to produce, as output, a chat message object containing the room identifier, user identifier, timestamp, and message text, and sends this chat message object to the server over the communication channel.

### Step 11

Server processes chat messages and distributes them. Server takes, as input, chat message objects from terminals, and performs validation, optional content filtering, and logging operations. Server inserts the message into a message log table in a database with fields for sender, channel, text content, and time. Server then performs a routing operation, selecting all participants currently registered in the relevant chat channel, and generates, as output, broadcast messages containing the chat content and sender information. Server transmits these broadcast messages to the terminals of the channel participants.

### Step 12

Terminal receives chat broadcast messages. Terminal takes, as input, chat messages from the server, and performs a data append operation to extend a local message list for the corresponding chat channel. Terminal computes layout information to display the messages in chronological order, with sender labels and time indicators. Terminal generates, as output, an updated chat panel view, and displays the new message lines so that the user can read the conversation in near real time.

### Step 13

User initiates voice communication. User selects a voice channel or presses a “Join Voice” button in the terminal interface. Terminal takes, as input, the user command and the target voice channel identifier, and requests access to a microphone using an audio capture interface. Terminal performs initialization of audio capture and encoding modules, and generates, as output, a voice session join request that includes channel information and media capabilities. Terminal sends the join request to the server and starts capturing raw audio samples from the microphone.

### Step 14

Server coordinates voice communication sessions. Server takes, as input, voice session join requests and media session descriptions from multiple terminals, and performs session management operations, including allocation of identifiers to audio streams and mapping of participants to channels. Server uses a media framework to process session description messages and to establish media paths. Server generates, as output, control messages and media routing instructions that are delivered to participating terminals or media relays, thereby enabling encoded audio packets from one terminal to be delivered to other terminals in the same voice channel.

### Step 15

Terminal captures and transmits audio data. Terminal takes, as input, raw audio samples obtained from the microphone at regular time intervals. Terminal performs signal processing operations such as framing, windowing, and compression using an audio codec. Terminal generates, as output, encoded audio packets containing compressed audio frames and header metadata, and transmits these packets to the server or a media relay according to a media transport protocol. Terminal simultaneously receives encoded audio packets from other participants, decodes them back into audio samples, and outputs them through a speaker or headphone interface so that the user can hear other users' voices.

### Step 16

User requests assistance from a generative AI model. User opens an AI assistance panel in the terminal and inputs a prompt sentence, for example, “What should I do next to successfully complete the team mission in this virtual room?” or “Give me a step-by-step plan to solve the current puzzle in this virtual environment.” Terminal takes, as input, the prompt sentence string and context identifiers such as room identifier and objective identifier. Terminal performs data packaging to produce, as output, an AI request message containing the prompt sentence, context identifiers, and user identifier, and sends this message to the server over a reliable communication channel.

### Step 17

Server performs context analysis for AI processing. Server takes, as input, the AI request message, including the prompt sentence and context identifiers. Server retrieves associated environment state data, recent chat messages, and recent user actions from the database and in-memory logs. Server then executes text processing algorithms on recent messages and prompt sentences, including tokenization and keyword extraction, and performs selection and summarization operations to construct compact context information. Server generates, as output, a structured context representation that captures relevant objective, participants, recent actions, and communication content.

### Step 18

Server constructs input for the generative AI model. Server takes, as input, the structured context representation and the prompt sentence. Server converts the prompt sentence and context elements into sequences of tokens using a tokenizer compatible with the generative AI model. Server then concatenates the tokens or arranges them according to a predefined input format, such as a sequence of role-labeled segments. Server generates, as output, a model input sequence comprising token identifiers and positional indices, suitable for direct consumption by the generative AI model.

### Step 19

Server applies the generative AI model to generate a proposal. Server takes, as input, the model input sequence and applies a transformer-based neural network model that is stored in memory. Server performs a series of matrix multiplications, non-linear activation operations, and attention weight computations across multiple layers to derive, for each position, an internal representation vector. Server then computes a probability distribution over vocabulary tokens for the next token and iteratively selects tokens according to a decoding algorithm such as greedy decoding or sampling. Server generates, as output, an output token sequence, which is then converted back into a natural language text string representing response data.

### Step 20

Server transforms the AI response into proposal information. Server takes, as input, the generated text string representing the response data. Server segments the text into structured components, such as numbered steps or bullet-point suggestions, by detecting delimiters and pattern markers. Server then maps references in the text to internal identifiers in the environment state data, for example by linking a mention of “team members” to participant identifiers and a mention of “current mission” to a specific objective identifier. Server generates, as output, proposal information objects that include fields such as description text, target participants, recommended actions, and priority level.

### Step 21

Server performs proposal presentation control. Server takes, as input, the proposal information objects and the current environment state and communication state. Server decides, using conditional logic and configuration rules, which proposals to present to which users and in what format. For example, server may select a text notification format, a visual highlight of objects, or a combination of both. Server encodes these decisions into presentation messages that include proposal content and user interface control instructions. Server generates, as output, presentation messages addressed to specific terminals or groups of terminals, and sends these messages over the communication channels.

### Step 22

Terminal receives and displays proposal information. Terminal takes, as input, proposal presentation messages from the server. Terminal interprets user interface control instructions and updates a local user interface model, adding new components such as informational panels, buttons to accept or ignore proposals, or graphical markers superimposed on the virtual environment. Terminal renders, as output, updated display content that shows the proposal text and any associated visual cues, such as highlighted paths or icons above relevant objects. User perceives the proposal information integrated into the virtual environment and can act on it immediately.

### Step 23

User reacts to proposals and continues interaction. User reads or listens to the proposal information and decides on a subsequent action, such as moving to a suggested location, starting a voice discussion, or executing a recommended task. User performs input operations through the terminal consistent with the chosen action. Terminal takes, as input, these subsequent user commands and again generates control messages or communication messages. Terminal sends these messages to the server, and the cycle of environment update, communication handling, and AI-assisted proposal generation continues, with the system using new inputs as additional data for future context analysis and proposal refinement.

### Application Example 2

Description follows regarding a flow of the specific processing in an Application Example 2. The units of the system described below are implemented by the data processing device 12 and the smart device 14. The data processing device 12 is called a “server” and the smart device 14 is called a “terminal”.

Conventional virtual environment systems and mixed-reality systems generally render content and script interactions in a static or preauthored manner. Even when some personalization is attempted, it is typically limited to simple parameter tuning or rule-based branching that does not fully utilize runtime user behavior, emotional state, or real-world operational data. As a result, the underlying computer system architecture and processing pipelines are not optimized to dynamically co-orchestrate generative artificial intelligence models, emotion estimation engines, and real-time interaction data in a unified control flow. In particular, existing systems exhibit several technical problems from the viewpoint of computer technology. First, server-side processing for interactive experiences is often fragmented into separate modules for content serving, user state tracking, and messaging, without a cohesive mechanism to generate machine-readable prompt sentences that incorporate heterogeneous runtime context (user behavior logs, emotion estimates, environment state, and external device status) for input to a generative AI model. This fragmentation leads to inefficient use of computational resources, redundant data transformations, increased network traffic between modules, and higher latency when generating scenario updates or virtual-entity responses.

Second, current systems generally fail to integrate emotion recognition into the core control loop for scenario generation. Emotion analysis, when present, is often treated as a peripheral feature that only triggers simple UI changes, rather than being used to dynamically adjust the content of prompts sent to a generative AI model, the resulting scenario data, and event data streamed back to the user device. Consequently, the system cannot efficiently adapt its output to the user's real-time emotional state, and the server cannot schedule or optimize processing based on emotion-driven priority or complexity requirements.

Third, traditional architectures do not provide an integrated mechanism for combining real-world work target status, such as sensor-based state information and progress information from external information processing apparatuses, with virtual environment control. There is no unified server that analyzes such real-world data, generates prompt sentences for a generative AI model, and automatically produces instruction messages, progress reports, or abnormality handling messages while simultaneously coordinating virtual entities and user-facing content. This absence of integration leads to separate, siloed systems for factory control and for virtual/augmented user interfaces, resulting in duplicated computation, inconsistent state representation, and non-optimal network usage.

Fourth, content generation workflows in existing systems typically rely on predesigned branching scripts or manually authored templates. They lack a server-level mechanism that deterministically structures prompt sentences for generative AI models in a manner that is consistent, context-rich, and tunable according to runtime system state. Without such a mechanism, the system cannot reliably produce coherent scenario data, event data, and virtual-entity response data that are synchronized with changing user behavior, emotional state, and external device status, leading to unstable user experiences and increased error handling complexity on the client side.

Accordingly, there is a need for an improved computer-implemented system and corresponding server architecture that: (i) centrally manages user behavior information, emotion information, and environment information as unified context; (ii) programmatically constructs and adjusts prompt sentences for a generative AI model based on that context; (iii) uses the resulting scenario data and event data to control the virtual environment and virtual entities in real time; and (iv) concurrently analyzes state information and progress information from real-world information processing apparatuses to generate coordinated messages. Such a system should improve computational efficiency, reduce latency, and enhance robustness in generating personalized, dynamically adapting experiences, thereby achieving a concrete improvement in the way computers orchestrate complex interactive experiences across virtual and real environments.

The specific processing by the specific processing unit 290 of the data processing device 12 in Application Example 2 is realized by the following means.

The present invention provides a server comprising a processor configured to provide an interface including a display unit and an input unit that allows a user to enter a virtual environment and participate in an activity for achieving a specific objective, to provide, via a communication path, a communication function that allows the user to transmit and receive information with another participant for cooperation toward the objective and to share activity-related information in real time, to present a virtual entity having an artificial intelligence function, to cause the virtual entity to respond dynamically according to behavior of the user, and to provide information and guidance that support progress of the activity, to construct, in a programmatic manner, a prompt sentence to be input to a generative AI model, the prompt sentence being generated based on a scenario-generation instruction prompt sentence acquired from the user and contextual information including behavior information, emotion information, and environment information of the user, to input the prompt sentence to the generative AI model and to cause the generative AI model to generate, as machine-processable output, scenario data relating to a user experience scenario, response data for the virtual entity, guidance data to be presented, and event data to be executed in the virtual environment, to determine, based on the scenario data and the event data, a story development, a branching pattern, an auxiliary event, and an alternative ending in the virtual environment dynamically, and to stream a result of the determination to a device of the user, to acquire sensory information and behavior information of the user including at least one of facial information, voice information, and action information of the user, and to estimate an emotional state of the user by using an emotion processing function that performs emotion estimation processing to recognize an emotion of the user, to adjust, based on the emotional state and the behavior information of the user, a content of the prompt sentence to be input to the generative AI model, a content of the response of the virtual entity, the scenario data, the event data, and presentation content in the virtual environment dynamically so as to provide a personalized experience for each user, and to analyze state information and progress information acquired from an information processing apparatus used by the user for a work target in a real environment, to generate a prompt sentence for the generative AI model based on an analysis result, and to automatically generate at least one of an instruction message, a progress report message, and an abnormality handling message for the information processing apparatus so as to support cooperative work between the work targets in the real environment and the user. This enables the server to centrally orchestrate generative AI model interactions, emotion estimation, scenario control, and external device messaging in a unified processing pipeline, thereby improving computer system performance by reducing redundant data transformations, lowering response latency, and providing consistent, context-aware, and personalized outputs across virtual and real environments.

The term “virtual environment” refers to a computer-generated environment in which a user can perceive and interact with objects, entities, and events via an electronic display and input devices, independently of or in combination with a physical environment.

The term “activity” refers to a sequence of operations, actions, or interactions performed by a user in the virtual environment for progressing toward or achieving a specific objective. The term “specific objective” refers to a goal, task, mission, or target condition that the system instructs or encourages the user to achieve through the activity in the virtual environment or in coordination with a real environment.

The term “interface” refers to a combination of hardware and software components, including at least a display unit and an input unit, that allows the user to view the virtual environment and to provide inputs such as commands, selections, or gestures to the system.

The term “display unit” refers to a hardware display component, such as a head-mounted display, a portable display device, or another image output device, that presents visual information representing the virtual environment, virtual entities, or system messages to the user.

The term “input unit” refers to a hardware input component, such as a controller, sensor, touch panel, microphone, or tracking device, that acquires user operation information including at least one of position information, posture information, gaze information, or command input.

The term “communication path” refers to a logical and physical communication channel, including wired or wireless networks and relevant communication protocols, that allows data to be transmitted between the server, user devices, and other participant devices.

The term “communication function” refers to a processing function that enables the exchange of messages, data, or control information between the user and another participant or system component via the communication path in real time or near real time.

The term “participant” refers to a human user, a software agent, or a device that participates in the activity in the virtual environment or in a related real-world task and can exchange information with the user.

The term “virtual entity” refers to a computer-generated agent, character, or object existing in the virtual environment that can present information and respond to user actions.

The term “artificial intelligence function” refers to a computational function implemented by one or more algorithms that simulate or approximate human-like reasoning, decision-making, or learning to determine responses or actions of the virtual entity.

The term “behavior of the user” refers to operations, actions, or interaction patterns performed by the user, including movements, selections, commands, and other interaction events observed by the system in the virtual or real environment.

The term “information and guidance” refers to content that instructs, advises, explains, or hints to the user how to proceed with the activity, achieve the specific objective, or respond to events in the virtual or real environment.

The term “generative AI model” refers to an artificial intelligence model that, when provided with an input including at least one prompt sentence, generates output data such as natural language text, scenario structures, or event descriptions according to learned patterns.

The term “prompt sentence” refers to a textual or structured data representation that instructs the generative AI model regarding a desired content, style, or purpose of generated output, including at least a scenario-generation instruction prompt sentence and contextual information.

The term “scenario-generation instruction prompt sentence” refers to a type of prompt sentence that specifies to the generative AI model a request to generate or modify a user experience scenario, including constraints or objectives relevant to the scenario.

The term “contextual information” refers to data describing the current or recent state associated with the user, including at least behavior information, emotion information, and environment information, and optionally including device status and interaction history.

The term “behavior information” refers to data representing actions, operations, or interaction events of the user, such as movements in the virtual environment, selections of items, timing of actions, and interaction sequences.

The term “emotion information” refers to data representing an estimated emotional state of the user, obtained from analysis of sensory information such as facial information, voice information, or action information.

The term “environment information” refers to data representing the state of the virtual environment or relevant aspects of the real environment, including scene identifiers, task states, device status, and external conditions.

The term “scenario data” refers to machine-processable data that specifies a structure or sequence of events, states, or narrative elements composing a user experience scenario in the virtual environment.

The term “response data” refers to data generated for the virtual entity that specifies at least one of natural language utterances, actions, animations, or other outputs to be presented in response to user behavior or system state.

The term “guidance data” refers to data specifying instructions, hints, explanations, or suggestions to be presented to the user for assisting the activity or clarifying system behavior.

The term “event data” refers to data describing one or more events to be executed in the virtual environment, including triggers, conditions, effects, and parameters for controlling changes in the environment or virtual entities.

The term “story development” refers to a progression of narrative states, events, or scenes in the virtual environment, including changes in objectives, challenges, and outcomes over time.

The term “branching pattern” refers to a structure of alternative story paths or scenario options that can be selected based on user behavior, system decisions, or randomization.

The term “auxiliary event” refers to an additional event in the virtual environment that is not strictly required to achieve the specific objective but that enhances, modifies, or supplements the user experience.

The term “alternative ending” refers to a terminal state or final outcome of the scenario that is different from another possible terminal state and that can be selected or generated based on user behavior, emotion, or system decisions.

The term “device of the user” refers to an electronic apparatus used by the user, including at least one of a head-mounted display device, a portable display device, a computing device, or a combination thereof, that executes client-side functions of the system.

The term “sensory information” refers to data captured from sensors associated with the user, including but not limited to image data of the face, audio data of the voice, motion data, and other physiological or behavioral signals.

The term “facial information” refers to image or feature data describing a face of the user obtained from at least one imaging sensor, suitable for analyzing expressions or related characteristics.

The term “voice information” refers to audio data representing speech, tone, pitch, loudness, or other acoustic characteristics of vocal sounds produced by the user.

The term “action information” refers to data capturing physical or virtual actions of the user, such as body movements, controller inputs, gesture inputs, or interaction events in the virtual environment.

The term “emotion processing function” refers to software and/or hardware logic configured to receive sensory information and behavior information and to perform emotion estimation processing for recognizing or classifying an emotional state of the user.

The term “emotional state of the user” refers to an estimated mental or affective condition of the user at a given time, represented by one or more categories, levels, or vectors derived from emotion analysis.

The term “personalized experience” refers to an experience in the virtual environment whose content, pacing, difficulty, narrative, or presentation is dynamically adapted based on at least one of behavior information, emotion information, and environment information of the specific user.

The term “work target” refers to a task, process, physical object, or operational unit in a real environment for which the user or a device performs work or monitoring.

The term “real environment” refers to a physical environment outside the virtual environment, including workplaces, facilities, or other real-world contexts in which work targets and information processing apparatuses operate.

The term “information processing apparatus” refers to an electronic device equipped with computing capability that can acquire, process, and transmit data relating to a work target, including at least sensors, actuators, or controllers.

The term “state information” refers to data indicating a current condition, status, or configuration of the information processing apparatus or associated work target, such as operational mode, error state, or resource level.

The term “progress information” refers to data indicating an advancement or completion level of a task or operation associated with the work target, such as percentage complete, remaining time, or step index.

The term “instruction message” refers to a machine-readable and/or human-readable message generated by the server that instructs an information processing apparatus or a user to perform a specific control action or operational step.

The term “progress report message” refers to a message generated by the server that describes a current or updated progress status of a work target or associated task to an information processing apparatus or a user.

The term “abnormality handling message” refers to a message generated by the server that describes a detected abnormal condition and one or more corresponding handling actions, countermeasures, or notifications for an information processing apparatus or a user.

The term “cooperative work” refers to work in which two or more participants, including at least one user and at least one work target or information processing apparatus, coordinate actions or information exchange to achieve a shared objective.

The term “server” refers to one or more computing devices configured to execute the processor-based functions described in the claims, including prompt construction, generative AI model interaction, emotion estimation, scenario control, and external device messaging.

The term “streaming” refers to transmitting data from the server to the device of the user in a manner that allows the device to sequentially receive and present the data while additional portions of the data are still being generated or transmitted.

The term “processor” refers to one or more processing units, including central processing units, graphics processing units, or dedicated accelerators, configured to execute instructions implementing the functions of the server.

In one embodiment, a server, one or more terminals, and one or more information processing apparatuses cooperate to implement the claimed system. The server includes at least one processor, a main memory, a non-volatile storage device, and a network interface. The server executes an operating system and a plurality of application modules implementing an interaction engine, a prompt construction engine, a generative AI interface, a scenario controller, an emotion processing engine, and an external device interface. The terminal includes at least one processor, a display unit, an input unit, and, in some embodiments, sensors such as a camera, microphone, and motion sensors. The user operates the terminal to access a virtual environment, to interact with virtual entities, and to cooperate with real-world work targets via information processing apparatuses.

The server executes program instructions stored in the non-volatile storage device to provide the interface described in the claims. The server provides the interface by transmitting rendering instructions and user interface definitions to the terminal. The terminal renders the virtual environment using a graphics engine, such as a game engine, and displays virtual scenes, virtual entities, and system messages on the display unit. The terminal acquires user inputs from the input unit, including button presses, touch inputs, head pose changes, hand controller motions, and gaze direction estimates obtained from an eye-tracking subsystem, and transmits these inputs as structured interaction events to the server.

The server maintains internal data structures representing user sessions, virtual environment states, and external device states. In one implementation, the server stores, in a relational database or key-value store, tables including at least a user table, a session table, a behavior_log table, an emotion_log table, a scenario_state table, and an external_device_state table. Each behavior_log record contains fields such as user identifier, timestamp, environment identifier, action type, action parameters, and latency metrics. Each emotion_log record contains fields such as user identifier, timestamp, dominant emotion label, emotion confidence scores, and sensor quality metrics. The scenario_state table contains a representation of the scenario graph, including nodes corresponding to story states and edges corresponding to branching transitions, and also includes pointers to scenario data generated by the generative AI model.

The server implements the generative AI model interface as a separate module that communicates with a generative AI model running locally or on a separate computing node. In one embodiment, the generative AI model is implemented as a transformer-based neural network trained on natural language data and scenario-structure data. The neural network includes an embedding layer, a plurality of self-attention layers, and feed-forward layers. The server stores model parameters in a parameter store and loads them into accelerator devices such as graphics processing units to perform matrix multiplications and attention computations efficiently. The server uses a tokenization algorithm to convert each prompt sentence into a sequence of token identifiers, and uses a beam search or top-k sampling algorithm to decode generated output sequences.

The server constructs the prompt sentence by combining several structured elements. In one embodiment, the server maintains a context object in memory for each user session. This context object includes behavior information (recent actions, interaction patterns), emotion information (recent emotion labels and their confidences), and environment information (current scene identifier, active objectives, external device states). The server serializes this context object into a textual representation according to predefined templates. For example, the server may construct a prompt sentence such as:

“The user is exploring a medieval town in a virtual environment. The user is currently feeling joy. The user has obtained a magic key in the old library. The user asks: ‘What can I use this item for?’ Explain how the key is used, but do not reveal the exact location of the hidden door.”

In another example, when the server processes real-world external device information, the server constructs a prompt sentence such as:

“Robot A has detected a shortage of Part X (current inventory: 5, safety stock: 20). Robot B is responsible for replenishment. Generate a concise chat message requesting Robot B to replenish the part and a follow-up message to notify the human worker when replenishment is complete.”

The server encodes these prompt sentences and additional control parameters, such as maximum output length and style constraints, into the input format expected by the generative AI model. The generative AI model performs attention-based computations over the token sequences, calculates output logits at each decoding step, and generates scenario data, response data, guidance data, and event data. The server parses the generated text into internal data structures, such as dialogue segments, scene event descriptors, and branching directives. For example, the server may map a text sentence that describes an event (“fireworks appear in the central plaza and a festival begins”) into an event descriptor that specifies an event type, target location, start time, and visual effect parameters.

The server uses the emotion processing engine to compute the emotion information used in the context. The terminal acquires sensory information including facial images, voice signals, and motion trajectories. The terminal may perform preliminary preprocessing, such as down-sampling, cropping, or noise reduction, and transmits feature vectors or compressed frames to the server. The server applies an emotion recognition neural network composed, for example, of convolutional layers and recurrent layers for image sequences and a separate recurrent or transformer-based network for audio features. The server extracts features such as facial landmarks, mouth openness, eyebrow angles, pitch contours, spectral envelopes, and speech rate. The server feeds these features into the emotion network, which outputs a probability distribution over emotion classes. The server selects a dominant emotion class and stores it in the emotion_log table. The server also uses rule-based logic to combine short-term and long-term emotion estimates to avoid unstable fluctuations.

The server uses this emotion information to adjust not only presentation content but also internal computational decisions. For example, when the emotion processing engine detects high frustration, the server may choose to allocate additional computational resources to generate more detailed guidance by increasing the number of decoding steps or by switching to a larger generative AI model configuration. Conversely, when the emotion processing engine detects low engagement, the server may choose to generate shorter, more frequent events. This dynamic resource allocation improves computational efficiency and perceived responsiveness compared to systems that do not exploit emotion information in the control loop.

The server coordinates real-world information processing apparatuses through the external device interface. In one embodiment, the information processing apparatus is an industrial controller that provides state information such as operational status, error codes, and resource levels, and progress information such as job completion percentages and remaining times. The server receives periodic status messages from the information processing apparatus via a network protocol and updates the external_device_state table. The server applies anomaly detection algorithms, such as comparing observed metrics with predicted distributions generated by a recurrent neural network trained on historical sequences. When the server detects an anomaly, the server constructs a corresponding prompt sentence describing the anomaly, the context, and desired message type, and sends this prompt to the generative AI model to generate an instruction message, a progress report message, or an abnormality handling message.

The server uses the scenario controller to unify the outputs of the generative AI model and the state of the virtual environment and external devices. The scenario controller maintains a scenario graph representation where nodes correspond to story states and edges correspond to transitions conditioned on user behavior, emotion state, and external device status. The scenario controller updates this graph based on scenario data generated by the generative AI model. The server applies deterministic rules to ensure that generated scenario fragments are consistent with the current graph, resolving conflicts by, for example, rejecting branches that would violate physical constraints or external device states.

The server streams scenario data, response data, and event data to the terminal using a streaming protocol. The terminal interprets scenario data to update the displayed scene, to move virtual entities, and to schedule new events. The terminal uses response data to display dialogue in text form or to synthesize speech using a text-to-speech engine. The terminal applies event data to control visual effects, such as particle systems, lighting changes, and sound effects, so that the user experiences the story development, branching patterns, auxiliary events, and alternative endings generated by the server.

The system provides several technical improvements over conventional architectures. Because the server constructs prompt sentences from structured context objects that integrate behavior information, emotion information, and environment information, the server reduces the need for multiple ad hoc data transformation layers. The server uses a unified internal representation of user context and external device states to feed the generative AI model, resulting in fewer serialization and deserialization steps and reduced network round trips. The integration of emotion information into prompt construction and scenario control reduces the number of times the user must issue clarifying inputs and reduces redundant content generation, thereby reducing processing load and latency.

The server improves accuracy and stability of generated scenarios by constraining the generative AI model with explicit scenario graphs and event descriptors. The server uses post-processing rules to convert free-form natural language into structured data, thereby reducing parsing errors at the terminal and preventing inconsistent states in the virtual environment. This structured integration also reduces the amount of data that must be transmitted, because the server can send compact descriptors instead of large free-form text segments when appropriate.

In one embodiment, the server trains the generative AI model using supervised learning on pairs of prompt sentences and target scenario outputs. The server defines a loss function, such as a cross-entropy loss over token sequences or a composite loss that includes penalties for violating scenario constraints. The server updates model weights using a gradient-based optimization algorithm. The server may use data augmentation techniques, such as paraphrasing prompts, adding noise to context descriptions, or varying emotion labels, to improve robustness. The server may also use reinforcement learning to adjust model behavior according to user satisfaction scores and system performance metrics, thereby biasing the model toward outputs that reduce latency or error rates.

The server also trains the emotion processing engine using labeled datasets of facial images, audio clips, and action patterns. The server defines a loss function combining classification loss and temporal consistency penalties. The server updates neural network weights periodically as new data is collected during actual system usage. The server uses this continuous learning approach to adapt emotion recognition to different user populations and lighting or noise conditions. This improves the technical accuracy of emotion estimation and, in turn, improves the quality of prompt sentences and generated scenarios.

The system uses non-conventional rules for integrating emotion and behavior into prompt construction. For example, the server may apply a rule that, when sustained frustration is detected and a high number of failed attempts at a task are logged in the behavior_log table, the server must include explicit step-by-step instructions in the prompt sentence asking the generative AI model to generate a concise, procedural hint. An example prompt sentence in this case is:

“The user has failed the same puzzle three times and is showing signs of frustration. Generate a short, step-by-step hint that explains the next action without revealing the full solution. Use simple, direct language.”

By encoding such rules at the server level, the system ensures consistent and technically meaningful adjustments of AI behavior that are not merely automated human decision-making but are structural modifications of how data is prepared and processed by the computing system.

In another embodiment, the server uses the described mechanisms in a mixed-reality factory environment. The terminal may be a head-mounted display worn by the user in a factory. The terminal displays overlays of machine status, recommended actions, and virtual entities that explain machine issues. The server receives sensor data and progress information from multiple information processing apparatuses, constructs prompt sentences combining this data with user behavior and emotion, and generates messages that both control physical machines and update virtual scenes. In this way, the server directly influences machine control through AI-generated instructions, while also adjusting on-screen guidance. The integrated architecture reduces communication overhead because the same context object is used both for machine control decisions and for virtual environment updates.

The described system thus improves computer technology by providing a specific server architecture, data structures, and control flows that reduce redundant data processing, decrease response latency, improve accuracy and stability of scenario generation, and integrate emotion estimation and external device control into the core loop of generative AI-based interaction. The server, the terminal, and the user act cooperatively under these mechanisms so that the generative AI model and prompt sentence handling are tightly coupled with concrete, technical operations in both virtual and real environments, rather than being limited to abstract content generation.

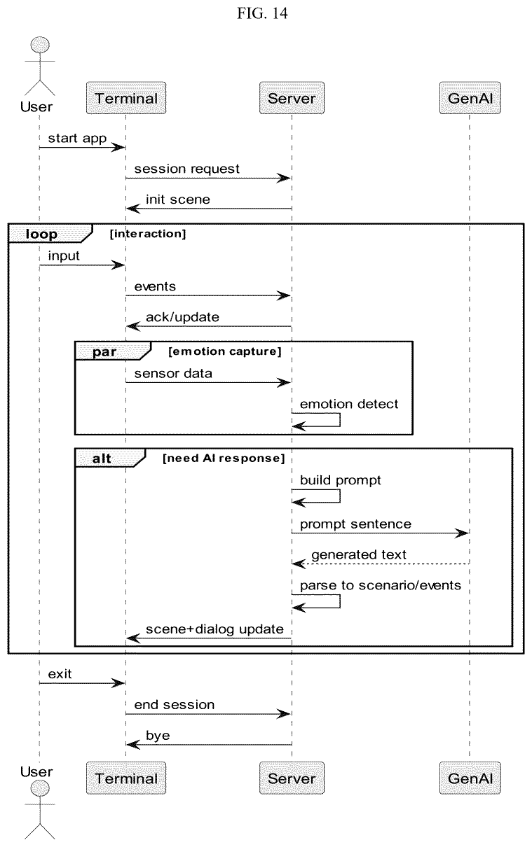

The following describes the processing flow using FIG. 14

### Step 1

User starts a session in the virtual environment.

User operates the terminal to launch an application and select entry into a virtual environment associated with a specific objective.

Input: User credentials, environment selection, and optional initial preferences.

Output: A session start request transmitted from the terminal to the server.

Terminal acquires the user input, packages the credentials and environment identifier into a structured message, and sends the message to the server via a communication path.

### Step 2

Server initializes session state and context objects.

Server authenticates the user, allocates a session identifier, and creates in-memory context objects containing default behavior information, emotion information, and environment information.

Input: Session start request containing user credentials and environment identifier.

Output: Session identifier, initial context object, and environment configuration sent to the terminal.

Server writes a new session record into a session table, initializes a scenario_state record for the selected environment, and transmits initial rendering parameters and user interface definitions to the terminal.

### Step 3

Terminal renders the initial virtual environment and begins capturing user interactions.

Terminal uses a graphics engine to draw the initial scene, place virtual entities, and show user interface elements, and starts monitoring input devices such as controllers, head tracking, and gaze tracking.

Input: Environment configuration and initial scenario data from the server.

Output: Interaction events generated and sent from the terminal to the server as the user moves and acts.

Terminal converts raw sensor readings (positions, button states, gaze vectors) into high-level events, such as “user moved to location L” or “user selected item I”, and timestamps these events before transmission.

### Step 4

Server logs behavior information and updates scenario state.

Server receives interaction events, appends them to a behavior_log table, and updates the scenario state record to reflect the current user position, progress, and active objectives.

Input: Interaction events from the terminal.

Output: Updated behavior_log entries and updated scenario_state entries stored on the server. Server applies data processing, such as mapping item identifiers to internal object references and computing derived features like frequency of attempts or time spent in a region.

### Step 5

Terminal acquires sensory information for emotion estimation.

Terminal periodically captures facial images from a camera, voice segments from a microphone, and motion traces from motion sensors while the user interacts with the environment.

Input: Raw sensor data from camera, microphone, and motion sensors.

Output: Preprocessed sensory data or feature vectors transmitted to the server.

Terminal performs local preprocessing, such as cropping face regions, normalizing audio volume, and compressing data, and then sends the processed data packets to the server at defined intervals.

### Step 6

Server estimates the emotional state of the user.

Server receives sensory data and uses an emotion processing engine to calculate emotion scores and determine the current emotional state.

Input: Sensory data packets and associated timestamps.

Output: Emotion_log entries and an updated emotional state in the context object.

Server applies feature extraction (facial landmarks, pitch contours, movement intensity) and feeds these features into an emotion recognition neural network, which outputs probabilities for emotion classes; server selects the dominant class, records it, and updates the session context.

### Step 7

Server decides whether a generative response is required.

Server monitors the behavior_log and scenario_state to detect conditions that require a new generative AI response, such as a user question to a virtual entity, repeated task failure, or detection of an anomaly in an external device.

Input: Recent behavior_log entries, emotion_log entries, scenario_state, and external_device_state.

Output: A decision flag indicating that a new prompt sentence should be constructed, and a description of the intended response type.

Server applies rule-based logic, for example, checking whether the user has interacted with a virtual entity or whether an external device state has changed beyond a threshold, and then determines the appropriate response category (hint, narrative extension, machine instruction, or message).

### Step 8

Server constructs a context-rich prompt sentence for the generative AI model.

Server uses the context object to build a textual prompt that includes user behavior information, emotional state, and environment information, and optionally includes state information and progress information from external devices.

Input: Context object containing behavior information, emotion information, environment information, and external_device_state.

Output: A prompt sentence and associated control parameters prepared for the generative AI model.

Server applies template-based concatenation and conditional insertion of clauses, for example:

“The user is exploring a medieval town in a virtual environment. The user is currently feeling joy. The user has obtained a magic key in the old library. The user asks: ‘What can I use this item for?’ Explain how the key is used, but do not reveal the exact location of the hidden door.”

or

“Robot A has detected a shortage of Part X (current inventory: 5, safety stock: 20). Robot B is responsible for replenishment. Generate a concise chat message requesting Robot B to replenish the part and a follow-up message to notify the human worker when replenishment is complete.”

Server also sets parameters such as maximum output length and desired style.

### Step 9

Server encodes the prompt sentence and invokes the generative AI model.

Server tokenizes the prompt sentence, converts tokens into numerical identifiers, and passes the identifiers and control parameters to the generative AI model.

Input: Prompt sentence and generation parameters.

Output: Generated token sequences representing scenario data, response data, guidance data, and event data.

Server executes forward passes through the generative AI model, performing matrix multiplications and attention computations, and uses decoding algorithms such as beam search or sampling to produce output sequences.

### Step 10

Server parses generated output into structured scenario and event representations.

Server converts the generated token sequences back into text, segments the text into logical units, and maps those units into internal data structures.

Input: Generated token sequences from the generative AI model.

Output: Structured scenario data, response data for virtual entities, guidance data, and event data stored in scenario_state and related structures.

Server identifies dialogue lines, event descriptions, and branching indicators, and creates or updates nodes and edges in the scenario graph; server also creates event descriptors specifying event types, locations, and timing.

### Step 11

Server adjusts generated content based on emotional state and system constraints.

Server reviews the structured data and compares it against the current emotional state and system configuration to determine whether to trim, expand, or modify the content.

Input: Structured scenario data, response data, guidance data, event data, and current emotional state.

Output: Finalized content packages ready to be transmitted to the terminal and, if applicable, to external devices.

Server may shorten long outputs for frustrated users, insert additional hints for users with repeated failures, or remove overly complex branches when system resources are constrained.

### Step 12

Server updates the scenario state and prepares streaming packets.

Server writes the finalized scenario data and event data back to the scenario state table and composes compact streaming packets containing only the necessary changes.

Input: Finalized content packages and previous scenario_state.

Output: Streaming packets describing dialogue updates, scene changes, and new events. Server computes differences between the existing state and the new state to avoid resending unchanged data, thereby reducing network bandwidth requirements.

### Step 13

Terminal receives scenario updates and renders virtual entity responses.

Terminal receives streaming packets containing dialogue text, animation cues, and event descriptors and applies them to the virtual environment.

Input: Streaming packets from the server.

Output: Updated visual and auditory output on the display unit, including virtual entity responses and new events.

Terminal triggers animations on the virtual entity, displays text messages as subtitles or speech balloons, and uses a text-to-speech engine to synthesize voice in synchronization with animations.

### Step 14

Terminal executes events and environment modifications.

Terminal interprets event descriptors to activate or modify objects, visual effects, and sound effects in the virtual environment.

Input: Event data specifying event types, parameters, and timing.

Output: Modified virtual environment state presented to the user.

Terminal may spawn new non-player characters, start a fireworks effect, open a hidden door, or highlight relevant objects, and updates its local state representation accordingly.

### Step 15

User perceives changes and provides further input.

User observes the virtual entity's response and the resulting environment changes and then decides on a next action, such as moving, selecting an option, or speaking a question.

Input: Visual and auditory content presented by the terminal.

Output: New user inputs captured and converted into interaction events by the terminal.

User may, for example, follow guidance toward a new event location, accept or reject an instruction, or ask for more details, thereby generating new behavior information.

### Step 16

Server monitors external information processing apparatuses and updates external_device_state.

Server receives periodic messages from information processing apparatuses that report state information and progress information for real-world work targets.

Input: Device status messages including operational status, error codes, inventory levels, and progress metrics.

Output: Updated external_device_state entries and optional anomaly flags.

Server parses the messages, normalizes metrics, and applies anomaly detection rules or models to determine whether a deviation from normal operation exists.

### Step 17

Server generates instruction, progress report, or abnormality handling messages for external apparatuses.

Server, when an anomaly or specific condition is detected, uses the context object and external_device_state to construct a prompt sentence requesting an appropriate message and then calls the generative AI model.

Input: External_device_state, anomaly flags, and current user context.

Output: Generated instruction messages, progress report messages, or abnormality handling messages, expressed in machine-readable and/or human-readable form.

Server maps the generated messages into formats suitable for external device controllers and for presentation to the user via the terminal, and logs these messages in a communication log.

### Step 18

Terminal presents real-world related messages and overlays to the user.

Terminal receives messages concerning real-world work targets and displays status indicators, instruction text, and virtual overlays corresponding to the physical apparatuses.

Input: Real-world related messages and overlay descriptors from the server.

Output: Combined real-world and virtual information presented to the user.

Terminal may show arrows pointing to physical devices, textual explanations, and virtual assistants explaining the situation, enabling the user to coordinate actions with the external apparatuses.

### Step 19

Server iteratively refines models and rules based on logs.

Server periodically analyzes behavior_log, emotion_log, scenario_state transitions, and external_device_state histories to retrain or fine-tune internal models and adjust rule thresholds.

Input: Historical logs of behavior, emotion, scenarios, and device states.

Output: Updated model parameters and decision rules stored on the server.

Server computes performance metrics such as response latency, hint effectiveness, and anomaly detection accuracy, and uses these metrics to modify model weights and rule parameters to further improve processing speed, accuracy, and robustness.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Moreover, although the processing by the data processing system 10 described above was executed by the specific processing unit 290 of the data processing device 12 or by the control unit 46A of the smart device 14, the processing may be executed by a specific processing unit 290 of the data processing device 12 and a control unit 46A of the smart device 14. Moreover, the specific processing unit 290 of the data processing device 12 acquires and collects information needed for processing from the smart device 14 or from an external device or the like, and the smart device 14 acquires and collects information needed for processing from the data processing device 12 or from an external device or the like.

For example, a collection unit is implemented by the control unit 46A of the smart device 14 and/or by the specific processing unit 290 of the data processing device 12. For example, an acquisition unit acquires number-of-steps data using the camera 42 and/or the communication I/F 44 of the smart device 14, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the output device 40 of the smart device 14 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart device 14.

### Second Exemplary Embodiment

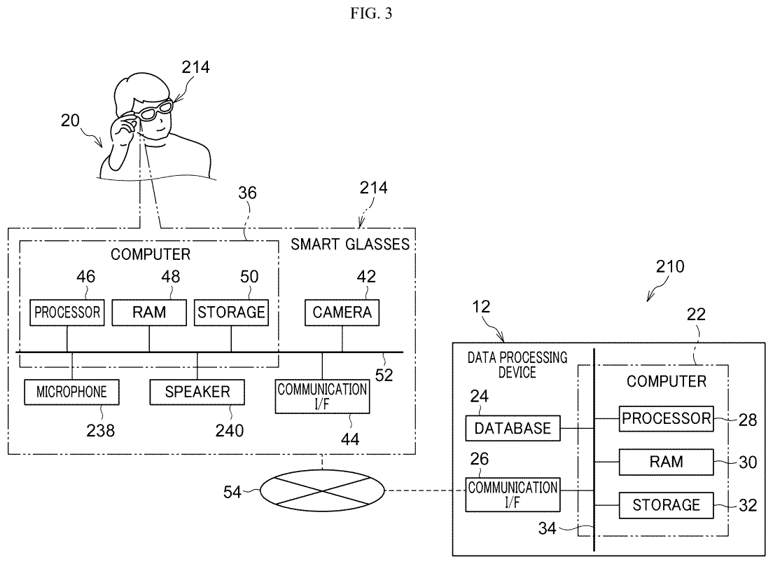

FIG. 3 illustrates an example of a configuration of a data processing system 210 according to a second exemplary embodiment.

As illustrated in FIG. 3, the data processing system 210 includes a data processing device 12 and smart glasses 214. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart glasses 214 include a computer 36, a microphone 238, a speaker 240, a camera 42, and a communication I/F 44. The computer 36 includes a processor 46, RAM 48, and storage 50. The processor 46, the RAM 48, and the storage 50 are connected to a bus 52. The microphone 238, the speaker 240, the camera 42, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

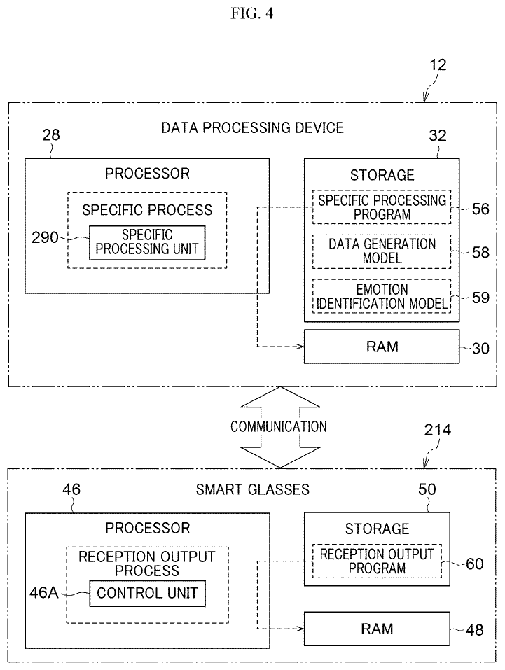

FIG. 4 illustrates an example of relevant functions of the data processing device 12 and the smart glasses 214. As illustrated in FIG. 4, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart glasses 214. A reception and output program 60 is stored in the storage 50. The processor 46 reads the reception and output program 60 from the storage 50 and in the RAM 48 executes the read reception and output program 60. The reception and output processing is implemented by the processor 46 operating as the control unit 46A according to the reception and output program 60 executed in the RAM 48. Note that a configuration may be adopted in which the smart glasses 214 include a data generation model and an emotion identification model similar to the data generation model 58 and the emotion identification model 59, and processing similar to the specific processing unit 290 is performed using these models.

Next, description follows regarding the specific processing by the specific processing unit 290 of the data processing device 12. The units of the system described below are implemented by the data processing device 12 and the smart glasses 214. In the following description the data processing device 12 is called a “server”, and the smart glasses 214 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the smart glasses 214. The control unit 46A in the smart glasses 214 outputs the specific processing result to the speaker 240. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the smart glasses 214, the processing may be executed by a specific processing unit 290 of the data processing device 12 and a control unit 46A of the smart glasses 214. Moreover, the specific processing unit 290 of the data processing device 12 acquires and collects information needed for processing from the smart glasses 214 or from an external device or the like, and the smart glasses 214 acquires and collects information needed for processing from the data processing device 12 or from an external device or the like.

For example, the collection unit is implemented by the control unit 46A of the smart glasses 214 and/or by the specific processing unit 290 of the data processing device 12. For example, an acquisition unit acquires number-of-steps data using the camera 42 and/or the communication I/F 44 of the smart glasses 214, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 of the smart glasses 214 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart glasses 214.

### Third Exemplary Embodiment

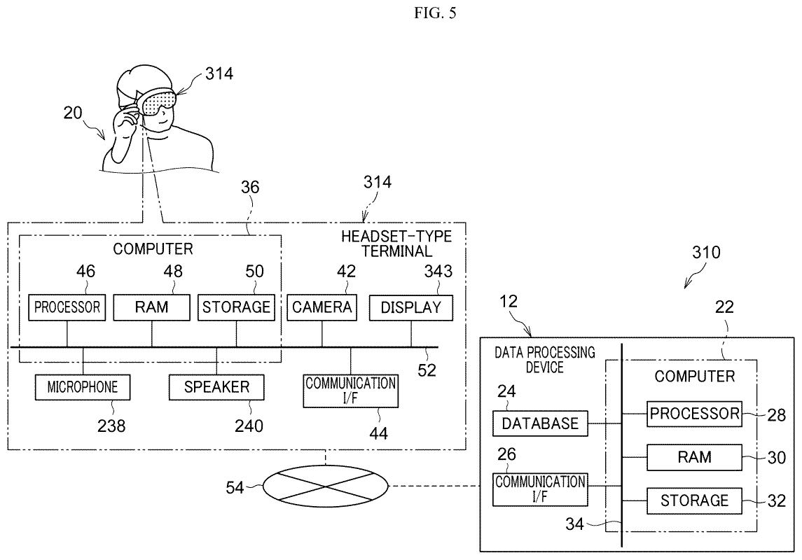

FIG. 5 illustrates an example of a configuration of a data processing system 310 according to a third exemplary embodiment.

As illustrated in FIG. 5, the data processing system 310 includes a data processing device 12 and a headset-type terminal 314. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The headset-type terminal 314 includes a computer 36, a microphone 238, a speaker 240, a camera 42, a communication I/F 44, and a display 343. The computer 36 includes a processor 46, RAM 48, and storage 50. The processor 46, the RAM 48, and the storage 50 are connected to a bus 52. The microphone 238, the speaker 240, the camera 42, the display 343, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

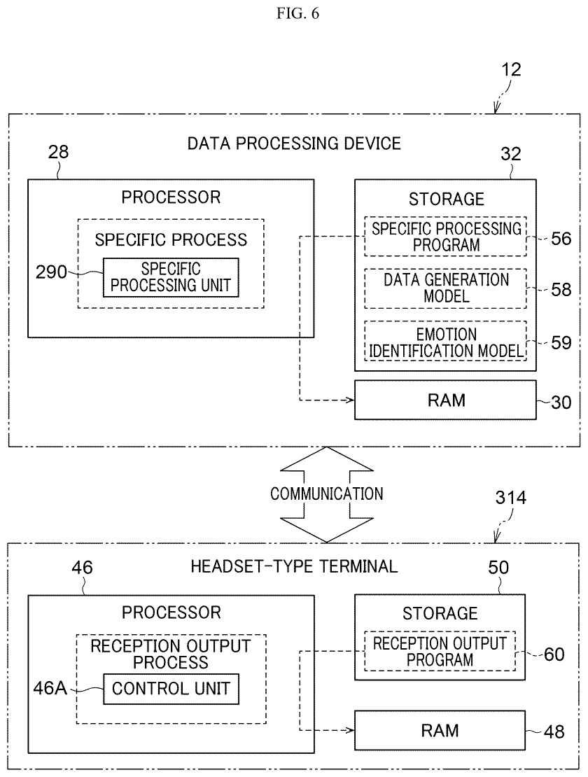

FIG. 6 illustrates an example of relevant functions of the data processing device 12 and the headset-type terminal 314. As illustrated in FIG. 6, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the headset-type terminal 314. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the headset-type terminal 314. In the following description the data processing device 12 is called a “server”, and the headset-type terminal 314 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the headset-type terminal 314. In the headset-type terminal 314, the control unit 46A outputs the result of the specific processing to the speaker 240 and the display 343. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the headset-type terminal 314, the processing may be executed by a specific processing unit 290 of the data processing device 12 and a control unit 46A of the headset-type terminal 314. Moreover, the specific processing unit 290 of the data processing device 12 acquires and collects information needed for processing from the headset-type terminal 314 or from an external device or the like, and the headset-type terminal 314 acquires and collects information needed for processing from the data processing device 12 or from an external device or the like.

For example, the collection unit is implemented by the control unit 46A of the headset-type terminal 314 and/or by the specific processing unit 290 of the data processing device 12. For example, an acquisition unit acquires number-of-steps data using the camera 42 and/or the communication I/F 44 of the headset-type terminal 314, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the display 343 of the headset-type terminal 314 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the headset-type terminal 314.

### Fourth Exemplary Embodiment

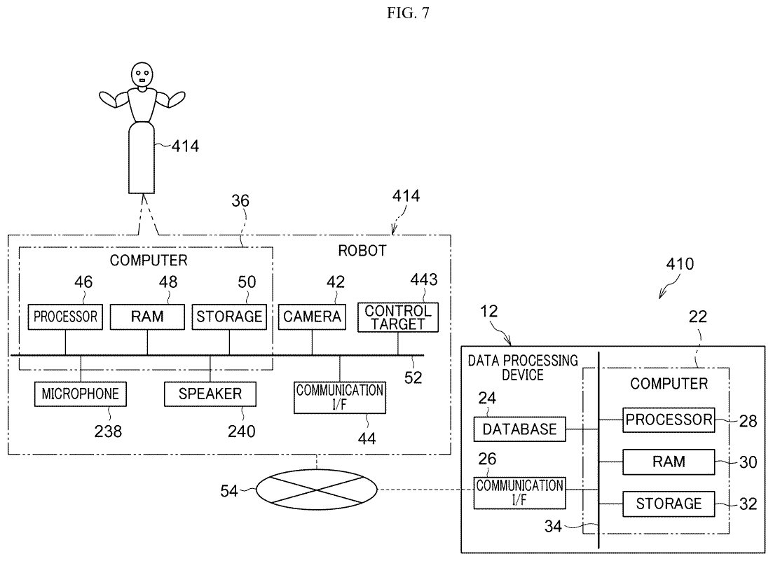

FIG. 7 illustrates an example of a configuration of a data processing system 410 according to a fourth exemplary embodiment

As illustrated in FIG. 7, the data processing system 410 includes a data processing device 12 and a robot 414. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The robot 414 includes a computer 36, a microphone 238, a speaker 240, a camera 42, a communication I/F 44, and a control target 443. The computer 36 includes a processor 46, RAM 48, and storage 50. The processor 46, the RAM 48, and the storage 50 are connected to a bus 52. The microphone 238, the speaker 240, the camera 42, the control target 443, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the robot 414 (for example, with an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

The control target 443 includes a display device, eye LEDs, and motors to drive arms, hands, feet, and the like. The posture and gesture of the robot 414 are controlled by controlling the motors of the arms, hands, feet, and the like. Part of an emotion of the robot 414 can be expressed by controlling these motors. Moreover, a facial expression of the robot 414 can be represented by controlling an illumination state of the eye LEDs of the robot 414.

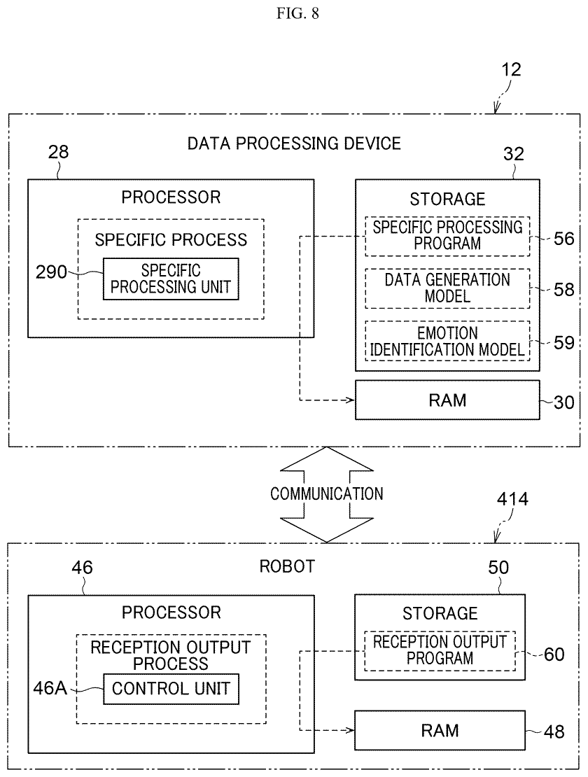

FIG. 8 illustrates an example of relevant functions of the data processing device 12 and the robot 414. As illustrated in FIG. 8, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the robot 414. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the robot 414. In the following description the data processing device 12 is called a “server”, and the robot 414 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the robot 414. In the robot 414, the control unit 46A outputs the result of the specific processing to the speaker 240 and the control target 443. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the robot 414, the processing may be executed by a specific processing unit 290 of the data processing device 12 and a control unit 46A of the robot 414. Moreover, the specific processing unit 290 of the data processing device 12 acquires and collects information needed for processing from the robot 414 or from an external device or the like, and the robot 414 acquires and collects information needed for processing from the data processing device 12 or from an external device or the like.

For example, the collection unit is implemented by the control unit 46A of the robot 414 and/or by the specific processing unit 290 of the data processing device 12. For example, an acquisition unit acquires number-of-steps data using the camera 42 and/or the communication I/F 44 of the robot 414, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the control target 443 of the robot 414 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the robot 414.

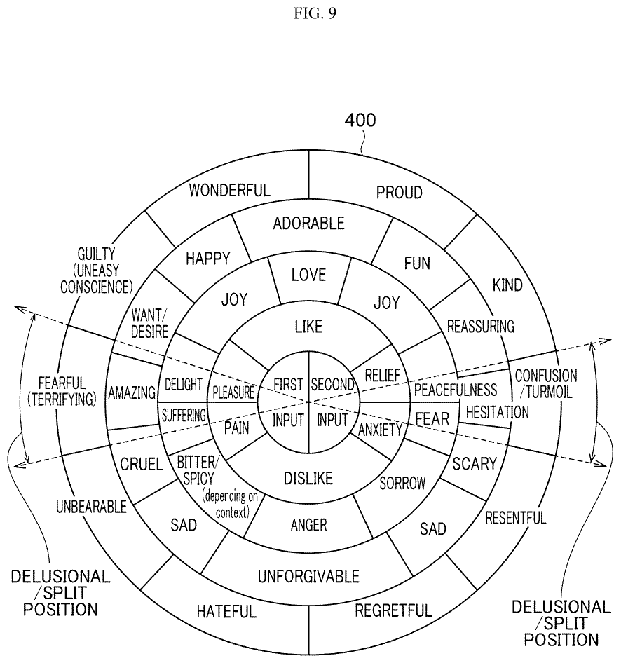

Note that the emotion identification model 59 serves as an emotion engine, and may decide the emotion of a user according to a specific mapping. Specifically, the emotion identification model 59 may decide the emotion of a user according to an emotion map (see FIG. 9) that is a specific mapping. Moreover, the emotion identification model 59 may also decide the emotion of the robot similarly, and the specific processing unit 290 may be configured so as to perform the specific processing using the emotion of the robot.

FIG. 9 is a diagram illustrating an emotion map 400 mapping plural emotions. In the emotion map 400, emotions are arranged in concentric circles that radiate out from the center. Primitive states of emotion are arranged nearer to the center of the concentric circles. Emotions expressing states and actions generated from states of mind are arranged further toward the outside of the concentric circles. Emotions are defined as including both affect and mental states. Emotions generated from reactions occurring in the brain are generally arranged at the left side of the concentric circles. Emotions induced by situational assessment are generally arranged at the right side of the concentric circles. Emotions generated from reactions occurring in the brain that are also emotions induced by situational assessment are generally arranged toward the top and toward the bottom of the concentric circles. Moreover, emotions of “euphoria” are arranged at the upper side of the concentric circles, and emotions of “dysphoria” are arranged at the lower side of the concentric circles. Plural emotions are accordingly mapped in this manner in the emotion map 400 based on a structure giving rise to emotions, and emotions that readily occur at the same time are mapped close to each other.

An example of such emotions is a distribution of emotions in the direction of 3 o'clock on the emotion map 400, generally around a boundary between relief and anxiety. Situational awareness dominates over internal sensations in the right half of the emotion map 400, with an impression of calm.

The inside of the emotion map 400 represents feelings, and the outside of the emotion map 400 represents actions, and so emotions further toward the outside of the emotion map 400 are more visible (are expressed by actions).

Human emotions are based on various balances, such as posture and blood sugar value balances, with a state of dysphoria being exhibited when these balances are far from ideal and a state of euphoria being exhibited when these balances are near to ideal. Even in a robot, a car, a motorbike, or the like, emotions can be thought of as being based on various balances such as orientation and remaining battery balances, with a state called dysphoria being exhibited when these balances are far from ideal and a state called euphoria being exhibited when these balances are near to ideal. An emotion map may, for example, be generated based on the emotion map of Dr. Mitsuyoshi (PhD Dissertation https://ci.nii.ac.jp/naid/500000375379: “Research on the phonetic recognition of feelings and a system for emotional physiological brain signal analysis”, Tokushima University). Emotions belonging to an area called “reaction” where feeling dominates are arranged in the left half of the emotion map. Moreover, emotions belonging to an area called “situation” where situational awareness dominates are arranged in the right half of the emotion map.

There are two types of emotion that facilitate leaning in an emotion map. One is an emotion in the vicinity of the center of negative “penitence” and “reflection” on the situational side. In other words, sometimes a negative “emotion” such as “I don't want to feel this way ever again” and “I don't want to be chided again” is experienced in a robot. Another is a positive emotion in the area of “desire” on the reaction side. In other words, there are times when a positive feeling such as “desire more” and “want to know more” is experienced.

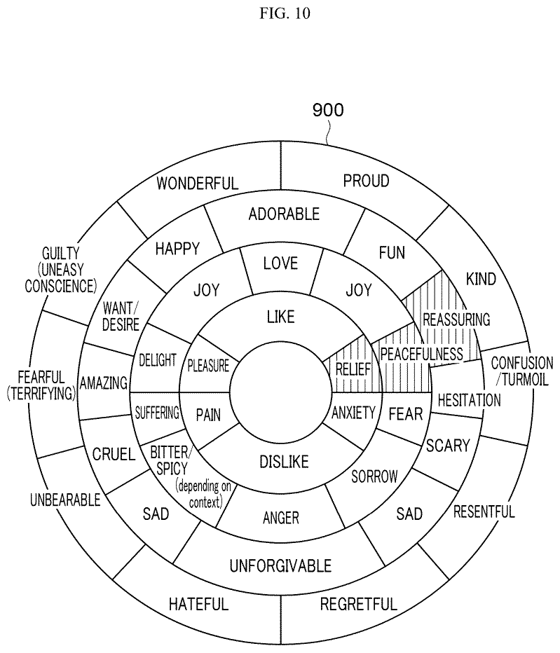

In the emotion identification model 59, user input is input to a pre-trained neural network, and emotion values indicating emotions shown on the emotion map 400 are acquired and the emotions of the user are decided. This neural network is pre-trained based on plural training data sets that each combine a user input with an emotion value indicating an emotion shown on the emotion map 400. The neural network is also trained such that emotions arranged close to each other have values that are close to each other, as in an emotion map 900 illustrated in FIG. 10. In FIG. 10 the plural emotions of “relief”, “peaceful”, and “reassured” are indicated as an example of close emotion values.

Although the system according to the present disclosure has been described mainly as functions of the data processing device 12, the system according to the present disclosure is not limited to being implemented in a server. The system according to the present disclosure may be implemented as a general information processing system. The present disclosure may, for example, be implemented by a software program operating on a personal computer, and may be implemented by an application operating on a smartphone or the like. The method according to the present disclosure may also be supplied to a user in the form of Software as a Service (SaaS).

Although in the exemplary embodiments described above examples are given of embodiments in which the specific processing is performed by a single computer 22, technology disclosed herein is not limited thereto, and distributed processing may be performed for the specific processing, with the specific processing distributed across plural computers including the computer 22. For example, the data generation model 58 may be provided in a device external to the data processing device 12, such that data generation in response to input data is performed in the external device.

Although in the exemplary embodiments described above examples are described of embodiments in which the specific processing program 56 is stored in the storage 32, the technology disclosed herein is not limited thereto. For example, the specific processing program 56 may be stored on a portable, non-transitory, computer readable, storage medium, such as universal serial bus (USB) memory or the like. The specific processing program 56 stored on the non-transitory storage medium is then installed on the computer 22 of the data processing device 12. The processor 28 then executes the specific processing according to the specific processing program 56.

Moreover, the specific processing program 56 may be stored on a storage device, such as a server connected to the data processing device 12 over the network 54, with the specific processing program 56 then being downloaded in response to a request from the data processing device 12 and installed on the computer 22.

Note that there is no need to store the entire specific processing program 56 on the storage device, such as a server connected to the data processing device 12 over the network 54, or to store the entire specific processing program 56 on the storage 32, and part of the specific processing program 56 may be stored thereon.

Hardware resources for executing the specific processing may use various processors as listed below. Examples of processors include, for example, a CPU that is a general-purpose processor that functions as a hardware resource to execute the specific processing by executing software, namely a program. Moreover, the processor may, for example, be a dedicated electronic circuit that is a processor having a circuit configuration custom designed for executing the specific processing, such as a field-programmable gate array (FPGA), a programmable logic device (PLD), or an application specific integrated circuit (ASIC). Memory is inbuilt or connected to each of these processors, and the specific processing is executed by each of these processors using the memory.

The hardware resource that executes the specific processing may be configured from one of these various processors, or may be configured from a combination of two or more processors of the same or different type (for example, a combination of plural FPGAs, or a combination of a CPU and a FPGA). The hardware resource executing the specific processing may be a single processor.

Examples of configurations of a single processor include, firstly, a configuration of a single processor resulting from combining one or more CPU and software, in an embodiment in which this processor functions as the hardware resource for executing the specific processing. Secondly, as typified by a System-on-chip (SOC) or the like, there is also an embodiment that uses a processor realized by a single IC chip to function as an overall system including plural hardware resources for executing the specific processing. Adopting such an approach means that the specific processing is realized using one or more of the various processors described above as hardware resource.

Furthermore, more specifically, an electrical circuit that combines circuit elements such as semiconductor elements or the like may be employed as a hardware structure of these various processors. The specific processing is merely an example thereof. This means that obviously redundant steps may be omitted, new steps may be added, and the processing sequence may be swapped around within a range not departing from the spirit of the present disclosure.

The described content and drawing content illustrated above are a detailed description of parts according to the present disclosure, and are merely examples of the present disclosure. For example, description related to the above configuration, function, operation, and advantageous effects is a description related to examples of the configuration, function, operation, and advantageous effects of parts according to the present disclosure. This means that obviously redundant parts may be eliminated, new elements may be added, and switching around may be performed on the described content and drawing content illustrated above within a range not departing from the spirit of the present disclosure. Moreover, to avoid misunderstanding and to facilitate understanding of parts according to the present disclosure, description related to common knowledge in the art and the like not particularly needing description to enable implementation of the present disclosure is omitted in the described content and drawing content illustrated as described above.

All publications, patent applications and technical standards mentioned in the present specification are incorporated by reference in the present specification to the same extent as if each individual publication, patent application, or technical standard was specifically and individually indicated to be incorporated by reference.

Note that, regarding the above description, the following supplementary notes are further disclosed.

### Example 1

### Supplementary 1

A system comprising a processor,
wherein the processor is configured to
provide, via an information processing apparatus, a display interface and an input interface that allow a user to enter a virtual space and participate in activities for achieving a predetermined goal,
provide a communication function that allows the user to cooperate with other participants for achieving the predetermined goal, and share, in real time, position information, operation information, and state information in the virtual space,
place, in the virtual space, a virtual character having an artificial intelligence function, dynamically update response content and behavior patterns of the virtual character in accordance with behavior data and emotion data of the user, and cause the virtual character to provide information that assists progress of the activities,
use a generative AI model to receive, from the user, a prompt sentence that instructs generation of a specific scenario, and generate, based on the prompt sentence, experience scenario data as structured data including environment information, object information, virtual character information, goal information, and interaction rule information,
set, based on the experience scenario data generated by the generative AI model, three-dimensional space configuration, physical behavior, path finding, and event control for an execution unit that executes a virtual space simulation, dynamically construct a virtual environment, and encode a simulation result as a time-continuous data sequence,
transmit the encoded simulation result and the experience scenario data to a terminal of the user by a streaming method, and cause the terminal to decode and render the simulation result and the experience scenario data so as to present the virtual space to the user in real time, acquire sensor data relating to expressions, voice, and behavior of the user, estimate an emotion state from the sensor data by an emotion estimation function, and dynamically change, in accordance with the emotion state, at least one of the experience scenario data, a configuration of the virtual environment, and the response content of the virtual character by an experience adjustment function,
acquire, as input events, movement operations, object operations, and dialogue operations performed by the user in the virtual space, update a progress state of the experience scenario data based on the input events, and generate and transmit, to the generative AI model, an additional prompt sentence including context information comprising the progress state and the input events so that the generative AI model sequentially generates at least one of an answer sentence of the virtual character, hint information, and a new event definition, and reflect the sequentially generated answer sentence, the hint information, and the new event definition in the virtual space simulation, and continuously transmit a result of the virtual space simulation to the terminal by the streaming method so as to provide the user with a dynamically changing experience scenario.

### Supplementary 2

The system according to supplementary 1,
wherein the processor is configured to
use at least one of virtual reality technology and augmented reality technology as the display interface and the input interface so as to provide an immersive experience to the user.

### Supplementary 3

The system according to supplementary 1,
wherein the processor is configured to
cause the virtual character having the artificial intelligence function to analyze the emotion state obtained by the emotion estimation function and the behavior data of the user, and adjust at least one of content, timing, and expression of information to be presented, thereby providing information that improves an experience of the user in the virtual space.

### Application Example 1

### Supplementary 1

A system comprising a processor,
wherein the processor is configured to
provide, through an interface, access for a user to enter a virtual space via a stereoscopic display device and to participate in activities for achieving a specific goal in the virtual space, provide a communication function that allows the user to cooperate with other participants for achieving the goal, and to share action information and state information in real time among a plurality of information processing devices by using the communication function, place an artificial-intelligence-based virtual entity in the virtual space, dynamically control the virtual entity in accordance with user action information and user emotion information, and cause the virtual entity to present guidance information for supporting progress of the activities,
generate a three-dimensional model of a virtual environment by using a three-dimensional generation development platform, convert the three-dimensional model into streaming data by performing compression processing and optimization processing, and sequentially transmit the streaming data to a terminal device of the user,
acquire interaction data including gaze information, posture information, and operation information from the terminal device of the user, and specify a selection content of a merchandise object in the virtual space on the basis of the interaction data,
search a merchandise information storage unit to acquire attribute information and three-dimensional shape data corresponding to the specified merchandise object, and transmit the attribute information and the three-dimensional shape data to the terminal device of the user,
convert the acquired three-dimensional shape data into a form applicable to a virtual representation of the user, execute data processing for generating a trial-use state of merchandise on the virtual representation, and thereby cause the terminal device to provide a virtual trial-use experience to the user,
receive input indicating a merchandise purchase intention from the user, execute consideration processing in cooperation with a settlement processing platform on the basis of the input, generate order information according to a result of the consideration processing, further execute delivery information generation in cooperation with a delivery management platform, and notify the order information and the delivery information to the terminal device of the user,
use a generative AI model to receive instruction information including a prompt sentence from the user, generate, on the basis of the prompt sentence and user behavior history data, a user-oriented experience scenario or recommendation information for merchandise, and reflect generated scenario data or the recommendation information in the virtual space, and execute emotion estimation processing that analyzes facial information, voice information, and action information of the user to estimate an emotion state, and dynamically adjust, according to the emotion state, at least one of display content in the virtual space, response content of the virtual entity, and presentation content of the recommendation information.

### Supplementary 2

The system according to supplementary 1,
wherein the processor is configured to
provide the interface by using at least one of virtual reality technology and augmented reality technology so as to provide the user with a stereoscopic and immersive experience, and cause the terminal device to render, in real time, the virtual space from the streaming data.

### Supplementary 3

The system according to supplementary 1,
wherein the processor is configured to
update the recommendation information for merchandise generated by the generative AI model on the basis of the user behavior history data and emotion state data, and cause the updated recommendation information to be displayed in a presentation area arranged in a predetermined region within the virtual space.

### Example 2

### Supplementary 1

A system comprising a processor,
wherein the processor is configured to
provide, to a user, an interface that controls display and input so that the user accesses a virtual environment and participates in an activity to achieve a predetermined objective, control communication so that a communication path is established with a user terminal and a plurality of types of communication data including character information and audio information are transmitted and received in real time to enable information sharing and cooperative work among users,
manage environment state data including position information in the virtual environment, object information, participant information, and information on an ongoing objective, update a state of the virtual environment based on the environment state data, and transmit an update result to the user terminal,
perform context analysis to extract context information relating to an objective that the user attempts to achieve in the virtual environment and to a progress state, from character input, audio input, or operation input received from the user terminal,
perform generative artificial intelligence cooperation to query a generative AI model using, as input data, the context information and a prompt sentence received from the user as an instruction sentence to the generative AI model, and to cause the generative AI model to generate response data including proposal information for achieving the objective based on the prompt sentence and the context information,
perform proposal presentation control to format the response data acquired from the generative AI model in association with the ongoing objective, a participant configuration, and a communication state in the virtual environment, transmit the formatted response data as the proposal information to the user terminal, and present to the user a next action candidate or a cooperation method, and
perform integrated session management to integrally manage a transmission and reception state of the character information, a transmission and reception state of the audio information, and a response acquisition state from the generative AI model, and dynamically switch display content and a user interface in the virtual environment according to these states.

### Supplementary 2

The system according to supplementary 1,
wherein the processor is configured to generate image information using virtual reality technology or augmented reality technology according to the state of the virtual environment, transmit the image information to the user terminal, and provide an immersive experience to the user.

### Supplementary 3

The system according to supplementary 1,
wherein the processor is configured to hold, as history data, a character input history of the user, an audio input history of the user, an action history of the user, and a past response history by the generative AI model, and perform history cooperation processing to provide the history data to the generative AI model together with the prompt sentence so that proposal information based on continuous dialogue context is generated.

### Application Example 2

### Supplementary 1

A system comprising a processor,
wherein the processor is configured to
provide an interface comprising a display unit and an input unit that allows a user to enter a virtual environment and participate in an activity for achieving a specific objective,
provide, via a communication path, a communication function that allows the user to transmit and receive information with another participant for cooperation toward the objective and to share activity-related information in real time,
present a virtual entity having an artificial intelligence function, cause the virtual entity to respond dynamically according to behavior of the user, and provide information and guidance that support progress of the activity,
construct a prompt sentence to be input to a generative AI model, the prompt sentence being generated based on a scenario-generation instruction prompt sentence acquired from the user and contextual information including behavior information, emotion information, and environment information of the user,
input the prompt sentence to the generative AI model and cause the generative AI model to generate scenario data relating to a user experience scenario, response data for the virtual entity, guidance data to be presented, and event data to be executed in the virtual environment,
determine, based on the scenario data and the event data, a story development, a branching pattern, an auxiliary event, and an alternative ending in the virtual environment dynamically, and stream a result of the determination to a device of the user,
acquire sensory information and behavior information of the user including at least one of facial information, voice information, and action information of the user, and estimate an emotional state of the user by using an emotion processing function that performs emotion estimation processing to recognize an emotion of the user,
adjust, based on the emotional state and the behavior information of the user, a content of the prompt sentence to be input to the generative AI model, a content of the response of the virtual entity, the scenario data, the event data, and presentation content in the virtual environment dynamically so as to provide a personalized experience for each user, and analyze state information and progress information acquired from an information processing apparatus used by the user for a work target in a real environment, generate a prompt sentence for the generative AI model based on an analysis result, and automatically generate at least one of an instruction message, a progress report message, and an abnormality handling message for the information processing apparatus so as to support cooperative work between the work targets in the real environment and the user.

### Supplementary 2

The system according to supplementary 1,
wherein the processor is configured to provide the interface for the user to enter the virtual environment by using a three-dimensional display technology or a real-space-superimposed display technology to provide an immersive experience to the user, to cause the display unit to present the virtual environment by using a head-mounted display device or a portable display device, and to cause the input unit to acquire user operation information including at least one of position information, posture information, and gaze information.

### Supplementary 3

The system according to supplementary 1,
wherein the processor is configured to cause the virtual entity having the artificial intelligence function to respond dynamically according to the behavior information and the emotional state of the user, to analyze the behavior information and the emotional state of the user, to adjust dialogue content, guidance content, hint content, event content, and an amount of information to be presented to the user, thereby providing information that improves an experience in the virtual environment, and to include the behavior information and the emotional state of the user in the prompt sentence for the generative AI model so as to generate different response patterns and scenario developments for each user.

What is claimed is:

1. A system comprising:
circuitry configured to:
receive, via a communication interface coupled to a packet-switched network, a prompt sentence from a terminal device specifying scenario generation parameters, and operate a generative neural network model using the prompt sentence to generate experience scenario data as structured data comprising environment configuration parameters, object attribute parameters, character behavior parameters, goal condition parameters, and interaction rule parameters;
configure an execution unit based on the experience scenario data by setting three-dimensional space geometry, physical simulation parameters, path-finding graph structures, and event control conditions, execute a virtual space simulation using the configured execution unit, and encode a simulation output as a time-continuous data stream;
transmit the encoded time-continuous data stream to the terminal device via the communication interface using a streaming protocol, and coordinate transmission of position information, operation information, and state information among a plurality of terminal devices sharing the virtual space;
acquire sensor data relating to expressions, voice, and behavior of a user from the terminal device via the communication interface, apply an emotion estimation function to the sensor data to compute an emotion state classification and intensity value, and transmit the emotion state classification and intensity value to the execution unit to dynamically update character behavior parameters and event control conditions; and
receive operation data from the terminal device via the communication interface, update virtual space state information in a storage device based on the operation data, and generate updated character behavior parameters by applying a neural network model to the operation data and the emotion state classification.

2. The system according to claim 1, wherein the circuitry is configured to operate the generative neural network model by tokenizing the prompt sentence, assembling a structured context comprising environment vocabulary terms, object vocabulary terms, and goal specification terms, and performing autoregressive generation to produce experience scenario data conforming to a predefined scenario schema.

3. The system according to claim 2, wherein the circuitry is configured to validate the generated experience scenario data against the predefined scenario schema by checking presence and type of required fields including environment configuration parameters, object attribute parameters, and interaction rule parameters, and regenerating experience scenario data for fields that fail schema validation.

4. The system according to claim 3, wherein the circuitry is configured to configure the three-dimensional space geometry by constructing a scene graph from the environment configuration parameters, instantiating object mesh representations based on the object attribute parameters, and computing spatial adjacency relationships and collision volumes.

5. The system according to claim 4, wherein the circuitry is configured to execute the virtual space simulation by applying a physics simulation procedure at a fixed time-step interval to update object positions, velocities, and collision states based on the physical simulation parameters, and applying the path-finding graph structures to compute movement trajectories for simulated entities.

6. The system according to claim 1, wherein the circuitry is configured to encode the simulation output as a time-continuous data stream by computing delta state representations between successive simulation time steps, compressing the delta state representations using an entropy coding procedure, and packetizing the compressed delta state representations into transmission units with sequence numbers.

7. The system according to claim 6, wherein the circuitry is configured to transmit the packetized transmission units using an adaptive bitrate streaming procedure that monitors a measured network throughput metric for the terminal device and adjusts a compression quality parameter based on the measured network throughput metric.

8. The system according to claim 1, wherein the circuitry is configured to apply the emotion estimation function by extracting facial action unit features from image frames in the sensor data, extracting prosodic features from audio data in the sensor data, and applying a multimodal fusion model that combines the facial action unit features and the prosodic features to compute emotion state probability distributions over an emotion state category set.

9. The system according to claim 8, wherein the circuitry is configured to update the character behavior parameters by applying a behavior update function that maps the emotion state classification and intensity value to a behavior pattern identifier, retrieving a behavior pattern specification corresponding to the behavior pattern identifier from the storage device, and injecting the behavior pattern specification into the event control conditions of the execution unit.

10. The system according to claim 9, wherein the circuitry is configured to accumulate a history of emotion state classifications and intensity values in the storage device indexed by session identifier, and generate an emotion trajectory representation from the accumulated history for use as additional context input to the generative neural network model when regenerating experience scenario data.

11. The system according to claim 1, wherein the circuitry is configured to coordinate transmission among a plurality of terminal devices by maintaining a shared virtual space state record in the storage device, broadcasting state update packets to each terminal device via the communication interface when position information, operation information, or state information changes, and applying a conflict resolution procedure to merge concurrent state updates from different terminal devices.

12. The system according to claim 11, wherein the circuitry is configured to apply the conflict resolution procedure by assigning a causal ordering to concurrent state update messages using a logical clock mechanism, and applying last-writer-wins or application-specific merge functions to resolve conflicting updates to the same virtual space state field.

13. The system according to claim 1, wherein the circuitry is configured to generate a character utterance response by constructing a character utterance prompt comprising the current virtual space state, the emotion state classification, the user operation data, and a character personality specification, and operating the generative neural network model using the character utterance prompt to generate natural language response text for output to the terminal device.

14. The system according to claim 13, wherein the circuitry is configured to convert the generated natural language response text to synthesized audio by applying a text-to-speech synthesis model, synchronize the synthesized audio with simulated character animation frames based on phoneme timing information, and include the synchronized animation and audio data in the time-continuous data stream.

15. The system according to claim 1, wherein the circuitry is configured to store experience scenario data, session state records, and emotion trajectory records in the storage device indexed by session identifier, and enable retrieval of prior session records by a subsequent prompt sentence from the terminal device to condition the generative neural network model on accumulated session history.

16. The system according to claim 15, wherein the circuitry is configured to generate a session summary by operating the generative neural network model with a summarization prompt comprising retrieved session state records and emotion trajectory records as input, and transmit the session summary to the terminal device via the communication interface.

17. The system according to claim 1, wherein the circuitry is configured to monitor a rendering performance metric reported by the terminal device via the communication interface, and when the rendering performance metric falls below a level-of-detail threshold, reduce the spatial resolution of environment configuration parameters and object attribute parameters in the experience scenario data transmitted to that terminal device.

18. A system comprising:
circuitry configured to:
receive, via a communication interface coupled to a packet-switched network, a prompt sentence from a terminal device, and operate a generative neural network model using the prompt sentence to generate experience scenario data as structured data comprising environment configuration parameters, object attribute parameters, character behavior parameters, goal condition parameters, and interaction rule parameters conforming to a predefined scenario schema;
configure an execution unit by constructing a scene graph from environment configuration parameters, setting physical simulation parameters and path-finding graph structures, and executing a virtual space simulation at a fixed time-step interval, encoding the simulation output as a time-continuous data stream using delta state compression and adaptive bitrate streaming;
transmit the time-continuous data stream to a plurality of terminal devices via the communication interface, and coordinate shared virtual space state updates using a conflict resolution procedure that applies a logical clock mechanism to concurrent state update messages;
acquire sensor data from a terminal device, apply a multimodal fusion model combining facial action unit features and prosodic features to compute an emotion state classification and intensity value, and update character behavior parameters and event control conditions of the execution unit based on the emotion state classification; and
generate character utterance responses by operating the generative neural network model with a character utterance prompt comprising virtual space state, emotion state classification, and character personality specification, convert generated response text to synthesized audio using a text-to-speech synthesis model, and include synchronized animation and audio data in the time-continuous data stream.

19. The system according to claim 18, wherein the circuitry is configured to accumulate emotion state classifications, intensity values, and virtual space state records in a storage device indexed by session identifier, and generate a session summary by operating the generative neural network model with a summarization prompt comprising retrieved session records.

20. A method comprising:
receiving, via a communication interface coupled to a packet-switched network, a prompt sentence from a terminal device specifying scenario generation parameters, and operating a generative neural network model using the prompt sentence to generate experience scenario data as structured data comprising environment configuration parameters, object attribute parameters, character behavior parameters, goal condition parameters, and interaction rule parameters;
configuring an execution unit based on the experience scenario data by setting three-dimensional space geometry, physical simulation parameters, path-finding graph structures, and event control conditions, executing a virtual space simulation using the configured execution unit, and encoding a simulation output as a time-continuous data stream;
transmitting the encoded time-continuous data stream to the terminal device via the communication interface using a streaming protocol, and coordinating transmission of position information, operation information, and state information among a plurality of terminal devices sharing the virtual space;
acquiring sensor data relating to expressions, voice, and behavior of a user from the terminal device via the communication interface, applying an emotion estimation function to the sensor data to compute an emotion state classification and intensity value, and transmitting the emotion state classification and intensity value to the execution unit to dynamically update character behavior parameters and event control conditions; and
receiving operation data from the terminal device via the communication interface, updating virtual space state information in a storage device based on the operation data, and generating updated character behavior parameters by applying a neural network model to the operation data and the emotion state classification.
